(19) United States
(12) Patent Application Publication
(10) Pub. No.: US 2010/0329026 A1
(43) Pub. Date: Dec. 30, 2010

(54) SEMICONDUCTOR MEMORY DEVICE WITH CHARGE ACCUMULATION LAYER

(76) Inventors: Mitsutoshi NAKAMURA, Yokohama-shi (JP); Takeshi Shimane, Matsudo-shi (JP); Michiru Hogyoku, Kamakura-shi (JP); Katsuaki Isobe, Yokohama-shi (JP); Naoyuki Shigyo, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/822,703

(22) Filed: Jun. 24, 2010

(30) Foreign Application Priority Data
Jun. 25, 2009 (JP) 2009-151252
Apr. 21, 2010 (JP) 2010-098186

(51) Int. Cl. G11C 16/06; G11C 16/04

(52) U.S. Cl. 365/185.21; 365/185.18

(57) ABSTRACT

According to one embodiment, a semiconductor memory device includes memory cells, first and second selection transistors, a source line, a temperature monitor, and a source line voltage controller. The memory cells are connected in series between a source of the first selection transistor and a drain of the second selection transistor. The temperature monitor monitors a temperature of the semiconductor substrate. The source line voltage controller applies a voltage to the source line, in a read operation, in such a manner that a potential difference between the source line and the semiconductor substrate increases according to a rise in the temperature monitored by the temperature monitor and that a reverse bias is applied between the source of the second selection transistor and the semiconductor substrate.

### CROSS-REFERENCE TO RELATED APPLICATIONS

This application is based upon and claims the benefit of priority from Japanese Patent Applications No. 2009-151252, filed Jun. 25, 2009; and No. 2010-098186, filed Apr. 21, 2010; the entire contents of both of which are incorporated herein by reference.

### FIELD

Embodiments described herein relate generally to a semiconductor memory device with a charge accumulation layer.

### BACKGROUND

In recent years, the application of nonvolatile NAND memory has been expanding. Its memory capacity has exceeded 1 GB and goes on increasing. With the memory capacity increasing steadily, the memory cells are miniaturized further, causing a cell transistor threshold variation problem because of the processing accuracy limit of device configuration, proximity effect, impurity variations, and others. In a nonvolatile NAND memory using multilevel technology which stores three levels or more of data in a single memory cell, three or more threshold distributions have to be set in a narrow voltage range. Since the margin between the threshold distributions is narrow, the variations in the threshold value become essentially a serious problem.

To cope with the threshold variation problem, various propositions have been made. Such propositions have been disclosed in, for example, Jpn. Pat. Appln. KOKAI Publication No. 2007-012151, Jpn. Pat. Appln. KOKAI Publication No. 2001-357687, Jpn. Pat. Appln. KOKAI Publication No. 2002-025285, and Jpn. Pat. Appln. KOKAI Publication No. 2009-522705. However, with the propositions, a change in the threshold value due to temperature might not be coped with sufficiently.

### BRIEF DESCRIPTION OF THE DRAWINGS

FIG. 1 is a block diagram of a NAND flash memory according to a first embodiment;

FIG. 2 is a circuit diagram of a memory cell array according to the first embodiment;

FIG. 3 is a plan view of a NAND cell unit according to the first embodiment;

FIG. 4 is a sectional view taken along line 4-4 of FIG. 3;

FIG. 5 is a graph showing the distribution of threshold values of a memory cell transistor according to the first embodiment;

FIG. 6 is a graph showing a voltage generated by a second voltage control circuit according to the first embodiment;

FIG. 7 is a circuit diagram to explain a read operation in the first embodiment;

FIG. 8 is a graph showing a word line voltage in a write operation in the first embodiment;

FIG. 9 is a circuit diagram of a NAND flash memory according to the first embodiment;

FIG. 10 is a graph showing the distribution of threshold values of a memory cell transistor according to the first embodiment;

FIGS. 11 and 12 are graphs showing the relationship between the control gate voltage and the cell current;

FIG. 13 is a table showing the relationship between the source line voltage and S-factor in the first embodiment;

FIG. 14 is a circuit diagram of a charge pump circuit according to a second embodiment;

FIGS. 15, 16 and 17 are graphs showing voltages generated by a second voltage circuit according to the second embodiment;

FIG. 18 is a block diagram of a NAND flash memory according to a third embodiment;

FIG. 19 is a graph showing a change in the sense level with respect to temperature in the third embodiment;

FIGS. 20, 21 and 22 are graphs showing the relationship between the control gate voltage and cell current in the third embodiment;

FIG. 23 is a circuit diagram of a sense amplifier according to a fourth embodiment;

FIG. 24 is a timing chart of various signals in a read operation in the fourth embodiment;

FIG. 25 is a graph showing a change in the sense level with respect to temperature in the fourth embodiment;

FIG. 26 is a block diagram of a NAND flash memory according to a fifth embodiment;

FIG. 27 is a block diagram of a NAND flash memory according to a sixth embodiment;

FIG. 28 is a circuit diagram of a latch timing generator circuit according to the sixth embodiment; and

FIGS. 29 and 30 are timing charts of various signals in a read operation in the sixth embodiment.

### DETAILED DESCRIPTION

In general, according to one embodiment, a plurality of memory cells; first and second selection transistors; a source line; a temperature monitor; and a source line voltage controller. The memory cells are formed on a semiconductor substrate and include a stacked gate including a charge accumulation layer. The first selection transistor and the second selection transistor are formed on the semiconductor substrate. The memory cells are connected in series between a source of the first selection transistor and a drain of the second selection transistor. The source line is connected to a source of the second selection transistor. The temperature monitor monitors a temperature of the semiconductor substrate. The source line voltage controller applies a voltage to the source line, in a read operation, in such a manner that a potential difference between the source line and the semiconductor substrate increases according to a rise in the temperature monitored by the temperature monitor and that a reverse bias is applied between the source of the second selection transistor and the semiconductor substrate.

### First Embodiment

A semiconductor memory device according to a first embodiment will be explained, taking a NAND flash memory as an example.

<Overall Configuration of NAND Flash Memory>

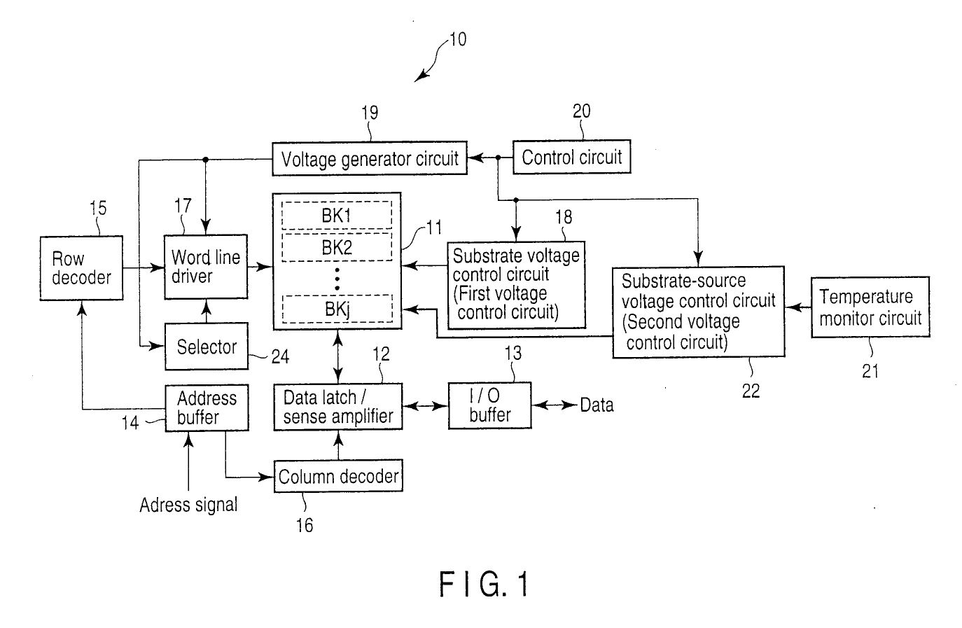

First, an overall configuration of a NAND flash memory according to the first embodiment will be explained with reference to FIG. 1. FIG. 1 is a block diagram schematically showing the configuration of a NAND flash memory according to the first embodiment. As shown in FIG. 1, the NAND flash memory 10 includes a memory cell array 11, a data latch/sense amplifier 12 (hereinafter, referred to as sense amplifier 12), an I/O buffer 13, an address buffer 14, a row decoder 15, a column decoder 16, a word line driver 17, a substrate voltage control circuit 18 (hereinafter, referred to as first voltage control circuit 18), a voltage generator circuit 19, a control circuit 20, a temperature monitor circuit 21, a substrate-source voltage control circuit 22 (hereinafter, referred to as second voltage control circuit 22), and a selector 24. These are integrated on the same semiconductor substrate.

The memory cell array 11 includes memory blocks BK1 to BKj (j is a natural number not less than 1) each of which is a set of a plurality of memory cell transistors capable of holding data. Each of the memory blocks includes a plurality of NAND cells. Hereinafter, when there is no need to distinguish between memory blocks BK1 to BKj, they will simply be referred to as memory blocks BK. The memory cell array 11 will be explained in detail later.

The sense amplifier 12 has the function of latching data in reading or programming data. The sense amplifier 12 includes, for example, a flip-flop circuit. In reading or verifying data, the sense amplifier 12 senses and amplifies the data read from a memory cell transistor and holds the amplified data. In programming data, the sense amplifier 12 temporarily holds data to be programmed in memory cell transistors and transfers the data to the memory cell transistors.

The I/O (Input/Output) buffer 13 functions as an interface circuit for data. That is, in reading data, the I/O buffer 13 receives the data held in the sense amplifier 12 and outputs the data to the outside. In reading data, the I/O buffer 13 receives data from the outside and transfers the data to the sense amplifier 12.

The address buffer 14 functions as an interface circuit for address signals. That is, in reading or writing data, the address buffer 14 receives a block address for specifying a memory block BK in the memory cell array 11, a page address for specifying a page in a memory block BK, and a column address for specifying a column. Then, the address buffer 14 transfers the block address and page address (which are sometimes simply referred to as row addresses) to the row decoder 15 and the column address to the column decoder 16.

Receiving a block address from the address buffer 14, the row decoder 15 decodes the address and selects one of the memory blocks BK in the memory cell array 11. The row decoder 15 further receives a page address from the address buffer 14, decodes the address, and selects one of the pages (a word line) in the selected memory block BK.

The word line driver 17 applies a necessary voltage to the word line in the memory block selected by the row decoder 15.

The column decoder 16 receives a column address from the address buffer 14, decodes the address, and selects a column direction (bit line) in the memory cell array 11.

The first voltage control circuit 18 controls the voltage of the semiconductor substrate. More specifically, the first voltage control circuit 18 applies a voltage to a p-well region (back gate) on which memory cell transistors are formed. For example, the first voltage control circuit 18 applies 0 V to the p-well region in a read or a write operation and a positive high voltage, for example, not lower than 15 V but not higher than 40 V to the p-well region.

The voltage generator circuit 19 generates a voltage in reading, writing, or erasing data.

Of a plurality of voltages generated by the voltage generator circuit 19, the selector 24 selects a voltage to be supplied to each word line in the selected block on the basis of the operation mode and information on the position of the selected word line or the like.

The temperature monitor circuit 21 measures the temperature of the semiconductor substrate on which the NAND flash memory 10 has been formed. Then, the temperature monitor circuit 21 supplies the measurement result to the second voltage control circuit 22.

The second voltage control circuit 22 controls the voltage difference between the semiconductor substrate and the source line of the memory cell array. More specifically, the second voltage control circuit 22 applies a voltage to the source line of the memory cell array. Under the control of the control circuit 20, the second voltage control circuit 22 controls a voltage applied to the source line on the basis of information supplied from the temperature monitor circuit 21.

The control circuit 20 supervises the overall operation of the NAND flash memory 10. More specifically, the control circuit 20 controls the operations of the first voltage control circuit 18, voltage generator circuit 19, and second control circuit 22.

<Memory Cell Array 11>

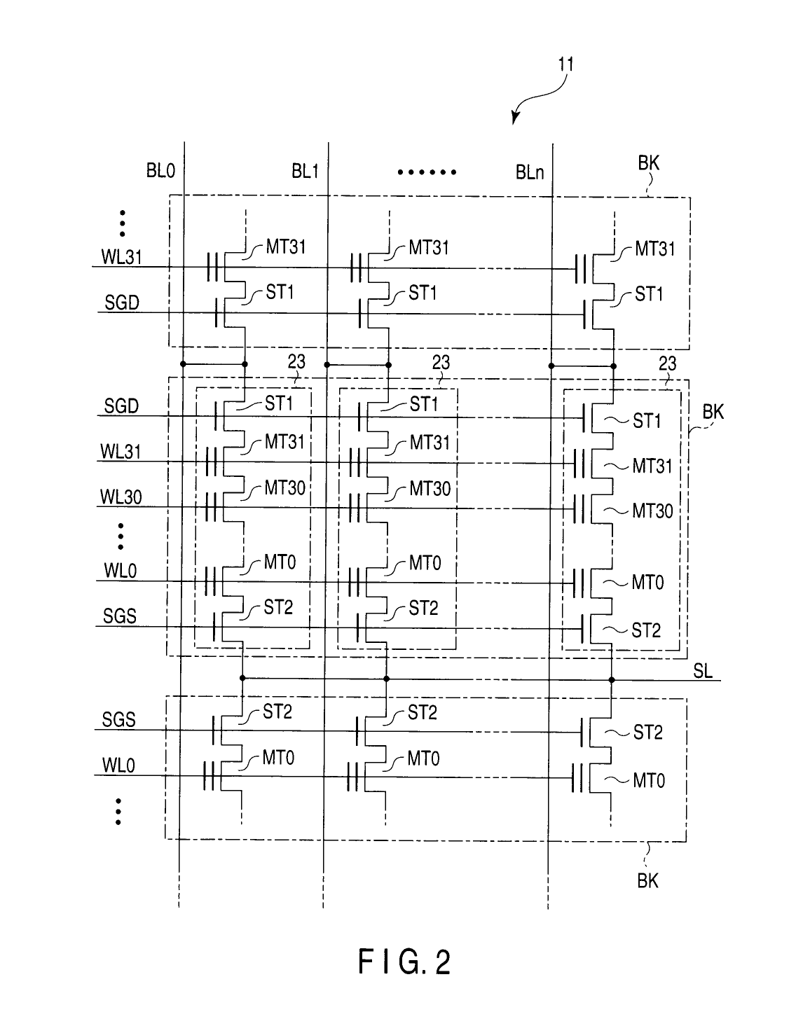

Next, the memory cell array 11 will be explained in detail with reference to FIG. 2. FIG. 2 is a circuit diagram of a part of the memory cell array 11.

As shown in FIG. 2, the memory cell array 11 includes a plurality of memory blocks BK. Each of the memory blocks includes a plurality of NAND cells 23. Each of the NAND cells 23 includes, for example, 32 memory cell transistors MT0 to MT31 and selection transistors ST1, ST2. Hereinafter, when there is no need to distinguish between memory cell transistors MT0 to MT31, they will simply be referred to as memory cell transistors MT. Each of the memory cell transistors MT has a stacked gate structure including a charge accumulation layer (e.g., a floating gate), formed on a semiconductor substrate with a gate insulating film interposed therebetween, and a control gate, formed on the charge accumulation layer with an inter-gate insulating film interposed therebetween. The number of memory cell transistors MT is not limited to 32 and may be 8, 16, 64, 128, and 256. That is, the number of memory cell transistors MT is not restrictive. The charge accumulation layer may be made of insulating material. Adjacent memory cell transistors MT share a source and a drain. The memory cell transistors MT are arranged between selection transistors ST1, ST2 in such a manner that their current paths are connected in series. The drain on one end side of the memory cell transistors MT in series connection is connected to the source of selection transistor ST1 and the source on the other end side is connected to the drain of selection transistor ST2.

The control gates of memory cell transistors MT in the same row are connected to any one of word lines WL0 to WL31 in a common connection manner. The gates of selection transistors ST1 of the memory cells in the same row are connected to a selection gate line SGD in a common connection manner. The gates of selection transistors ST2 of the memory cells in the same row are connected to a selection gate line SGS in a common connection manner. To simplify the explanation, word lines WL0 to WL31 will sometimes simply be referred to as word lines WL.

In the memory cell array 11, the memory blocks BK are arranged in a direction perpendicular to word lines WL. The drains of selection transistors ST1 in the same column are connected to any one of bit lines BL0 to BLn (n is a natural number) in a common connection manner. That is, bit lines BL0 to BLn are connected to the drains of selection transistors ST1 between the memory blocks BK. Bit lines BL0 to BLn will simply be called bit lines BL. The sources of selection transistors ST2 are connected to source line SL in a common connection manner.

Data is written or read simultaneously into or from a plurality of memory cell transistors MT connected to the same word line WL. This unit is called a page. Data is erased simultaneously from the NAND cells 23 in the same memory block BLK.

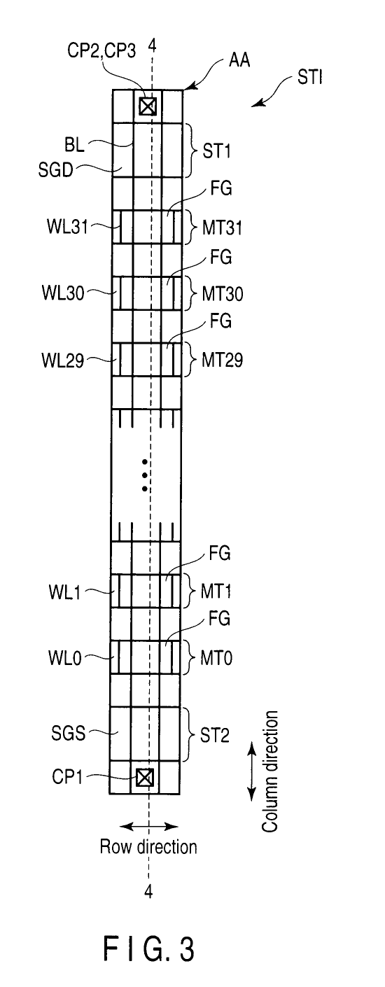

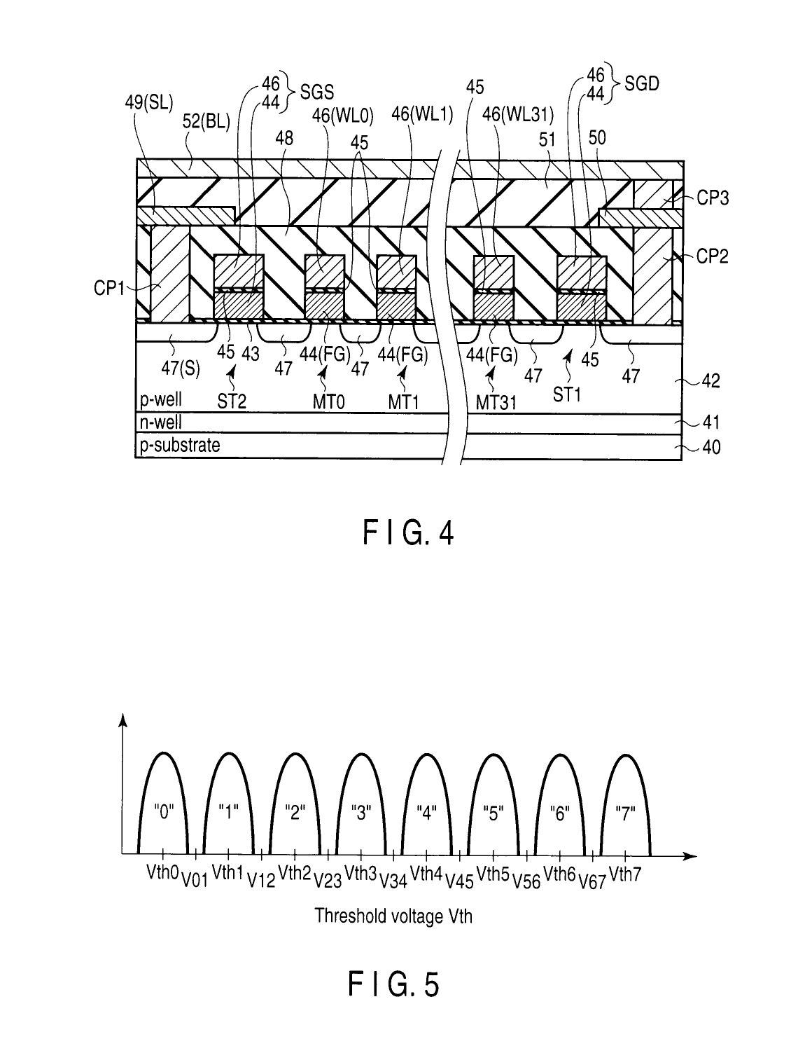

Next, the configuration of a NAND cell 23 included in the memory cell array 11 will be explained with reference to FIGS. 3 and 4. FIG. 3 is a plan view along the bit line of the NAND cell. FIG. 4 is a sectional view taken along line 4-4 of FIG. 3. Each of FIGS. 3 and 4 shows only one NAND cell 23.

As shown in FIG. 3, a plurality of strips of element regions AA extending in the column direction are provided in a p-type semiconductor substrate 40 (in FIG. 3, only one element region AA is shown). The element region AA is surrounded by an element isolating region STI. The element isolating regions STI separate the element regions AA electrically. On each of the element regions AA, memory cell transistors MT and selection transistors ST1, ST2 are formed.

An n-well region 41 is formed in the surface of the semiconductor substrate 40 and a p-well region 42 is formed in the surface of the n-well region 41. On the p-well region 42, a gate insulating film 43 is formed. On the gate insulating film 43, the gate electrodes of memory cell transistors MT and selection transistors ST1, ST2 are formed. Each of the gate electrodes of the memory cell transistors MT and selection transistors ST1, ST2 includes a polysilicon layer 44 formed on the gate insulating film 43, an inter-gate insulating film 45 formed on the polysilicon layer 44, and a polysilicon layer 46 formed on the inter-gate insulating film 45. The inter-gate insulating film 45 is formed of, for example, a silicon dioxide film, or an ON, an NO, or an ONO film which have a stacked structure of a silicon dioxide film and a silicon nitride film, or a stacked structure including those, or a stacked structure of a TiO₂, HfO₂, Al₂O₃, HfAlO_{X}, or HfAlSi film and a silicon dioxide or a silicon nitride film. The gate insulating film 43 functions as a tunnel insulating film.

In the memory cell transistors MT, the polysilicon layers 44 function as floating gates (FG). The polysilicon layers 46 adjacent in the row direction perpendicular to the column direction are connected to each other and function as a control gate electrode (word line WL). In selection transistors ST1, ST2, the polysilicon layers 44, 46 adjacent in the direction of the word line are connected to each other. The polysilicon layers 44, 46 function as selection gate lines SGS, SGD. Only the polysilicon layers 44 may function as selection gate lines. In this case, the polysilicon layers 46 of selection transistors ST1, ST2 are set at a specific potential or in a floating state. At the surface of the well region 42 between gate electrodes, an n⁺-type impurity diffused layer 47 is formed. The impurity diffused layer 47, which is shared by adjacent transistors, functions as a source (S) or a drain (D). The region between a source and a drain adjacent to each other functions as a channel region serving as an electron moving region. These gate electrodes, impurity diffused layers 47, and channel regions form MOS transistors which function as memory cell transistors MT and selection transistors ST1, ST2.

On the semiconductor substrate 40, an interlayer insulating film 48 is formed so as to cover the memory cell transistors MT and selection transistors ST1, ST2. In the interlayer insulating film 48, a contact plug CP1 reaching the impurity diffused layer (source) 47 of selection transistor ST2 on the source side is formed. On the interlayer insulating film 48, a metal interconnection layer 49 connected to the contact plug CP1 is formed. The metal interconnection layer 49 functions as a part of source line SL. Further, in the interlayer insulating film 48, a contact plug CP2 reaching the impurity diffused layer (drain) 47 of selection transistor ST1 on the drain side is formed. On the interlayer insulating film 48, a metal interconnection layer 50 connected to the contact plug CP2 is formed.

On the interlayer insulating film 48, an interlayer insulating film 51 is formed so as to cover the metal interconnection layers 49, 50. In the interlayer insulating film 51, a contact plug CP3 reaching the metal interconnection layer 50 is formed. On the interlayer insulating film 51, a strip of metal interconnection layer 52 connected to a plurality of contact plugs CP3 is formed in the column direction. The metal interconnection layer 52 functions as a bit line BL.

Next, the distribution of threshold values of the memory cell transistor MT will be explained with reference to FIG. 5. In FIG. 5, the abscissa represents threshold voltage Vth and the ordinate represents the existing probability of memory cell transistor MT.

As shown in FIG. 5, each of the memory cell transistors MT can hold 8-level data (3-bit data). That is, the memory cell transistor MT can hold eight data items, “0,” “1,” “2,” “3,” . . . , “7” in that order, that is, in ascending order of threshold voltage Vth. Threshold voltage Vth0 of “0” data in the memory cell transistor MT satisfies the expression Vth0<V01. Threshold voltage Vth1 of “1” data satisfies the expression V01<Vth1<V12. Threshold voltage Vth2 of “2” data satisfies the expression V12<Vth2<V23. Threshold voltage Vth3 of “3” data satisfies the expression V23<Vth3<V34. Threshold voltage Vth4 of “4” data satisfies the expression V34<Vth4<V45. Threshold voltage Vth5 of “5” data satisfies the expression V45<Vth5<V56. Threshold voltage Vth6 of “6” data satisfies the expression V56<Vth6<V67. Threshold voltage Vth7 of “7” data satisfies the expression V67<Vth7.

For example, voltage V01 is zero. That is, threshold voltage Vth0 of “0” data is negative and threshold voltages Vth1 to Vth7 of “1” to “7” data are positive. The 0-V read level is not limited to voltage V01 and may be voltage V12 or V23. Data the memory cell transistor MT can hold is not limited to the above eight levels. For instance, the data may be 2-level data (1-bit data), 4-level data (2-bit data), or 16-level data (4-bit data).

<Second Voltage Control Circuit>

Next, the second voltage control circuit 22 will be explained in detail. As described above, the second voltage control circuit 22 generates a voltage and supplies the voltage to source line SL. At this time, particularly when data is read, the second voltage control circuit 22 controls the voltage on the basis of temperature information supplied from the temperature monitor circuit 21. That is, on the basis of the temperature information, the second voltage control circuit 22 controls the potential difference between source line SL and p-well region 42.

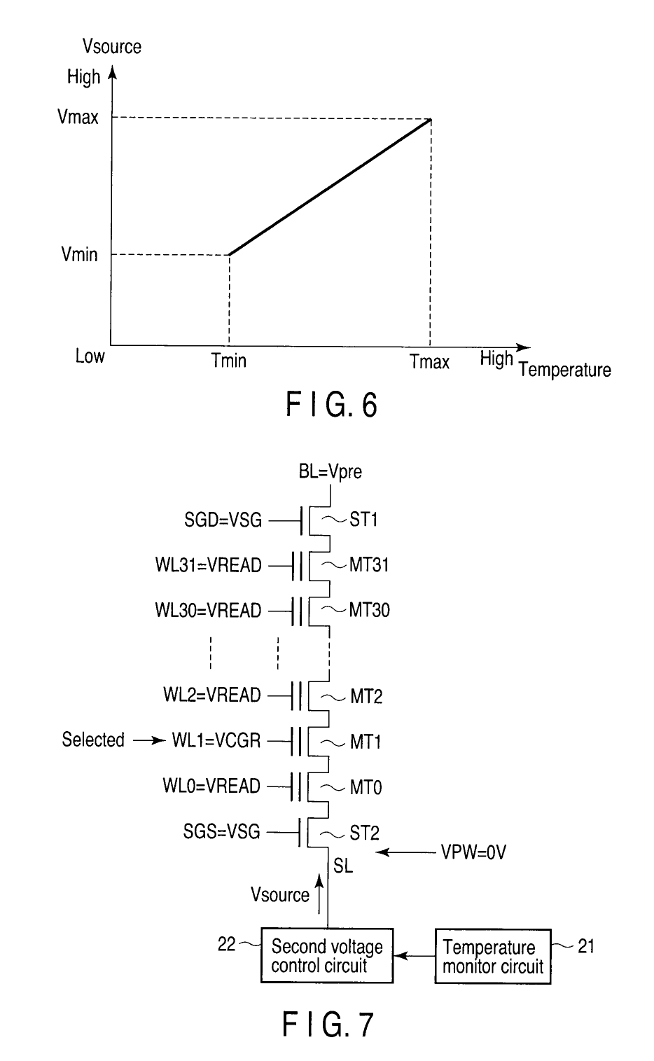

FIG. 6 is a graph showing the temperature dependence of voltage Vsource generated by the second voltage control circuit 22 in reading data. FIG. 6 is based on the assumption that the potential of the well region 42 is zero. Hereinafter, explanation will be given under this assumption. However, when the potential of the well region 42 is other than zero or can be varied with temperature, the second voltage control circuit 22 controls the potential of source line SL so that a potential difference equivalent to Vsource may applied between the well region 42 and source line SL.

As shown in FIG. 6, the second voltage control circuit 22 increases Vsource as the temperature rises. If the minimum value of the operating temperature range of the NAND flash memory 10 of the first embodiment is Tmin and the maximum is Tmax, as the temperature rises from Tmin to Tmax, Vsource rises continuously from its minimum Vmin to its maximum Vmax.

<Read Operation>

Next, a read operation in the NAND flash memory 10 configured as described above will be explained with reference to FIG. 7. FIG. 7 is a circuit diagram of a part of the NAND flash memory 10 in reading data. Hereinafter, a case where data is read from memory cell transistor MT1 connected to word line WL1 will be explained, focusing on one NAND cell 23 in the selected memory block BK.

First, the sense amplifier 12 (not shown) precharges a bit line BL to set the potential of the bit line BL at VPRE (e.g., 0.7 V+Vsource). The first voltage control circuit 18 sets the potential VPW of the well region 42 to zero. The temperature monitor circuit 21 detects the temperature of the semiconductor substrate 40 (or the well region 42) and supplies the detected temperature to the second voltage control circuit 22. On the basis of the temperature information and the relationship as shown in FIG. 6, the second voltage control circuit 22 generates a voltage Vsource and applies Vsource to source line SL.

Then, the row decoder 15 selects word line WL1 and the word line driver 17 applies read voltage VCGR to the selected word line WL1. Read voltage VCGR varies depending on which one of the eight levels shown in FIG. 5 is read. For example, to determine whether the level is “0” level or not lower than “1” level, V01 is applied as voltage VCGR to the selected word line WL1.

In addition, the word line driver 17 applies voltage VREAD to the unselected word lines WL0, WL2 to WL31. Voltage VREAD is a voltage that turns on a memory cell transistor MT, regardless of the data the memory cell transistor holds.

Furthermore, the word line driver 17 applies voltage VSG to the selection gate lines SGD, SGS. Voltage VSG is a voltage that turns on selection transistors ST1, ST2.

As a result, the memory cell transistors MT0, MT2 to MT31 connected to the unselected word lines WL0, WL2 to WL31 are turned on, forming channels. Select transistors ST1, ST2 are also turned on.

Then, when the memory cell transistor MT connected to the selected word line WL1 is turned on, the bit line BL and source line SL go into the conducting state. That is, current flows from the bit line BL to the source line SL. When the memory cell transistor MT is turned off, the bit line BL and source line SL go into the nonconducting state. That is, no current flows from the bit line BL to source line SL. By the operation, data is read from all the bit lines simultaneously.

The sense amplifier 12 senses current flowing through the bit line BL and determines data, depending on whether the amount of current has exceeded a certain threshold value Ith.

<Write Operation>

Next, a write operation will be explained. Data is written by repeating a program operation and a verify operation. A program operation is the operation of injecting charges into the charge accumulation layer 44 by generating a potential difference between the control gate 36 and channel of the memory cell transistor MT. A verify operation is the operation of verifying whether the threshold voltage of the memory cell transistor MT has reached a desired value by reading data from the memory cell transistor MT programmed.

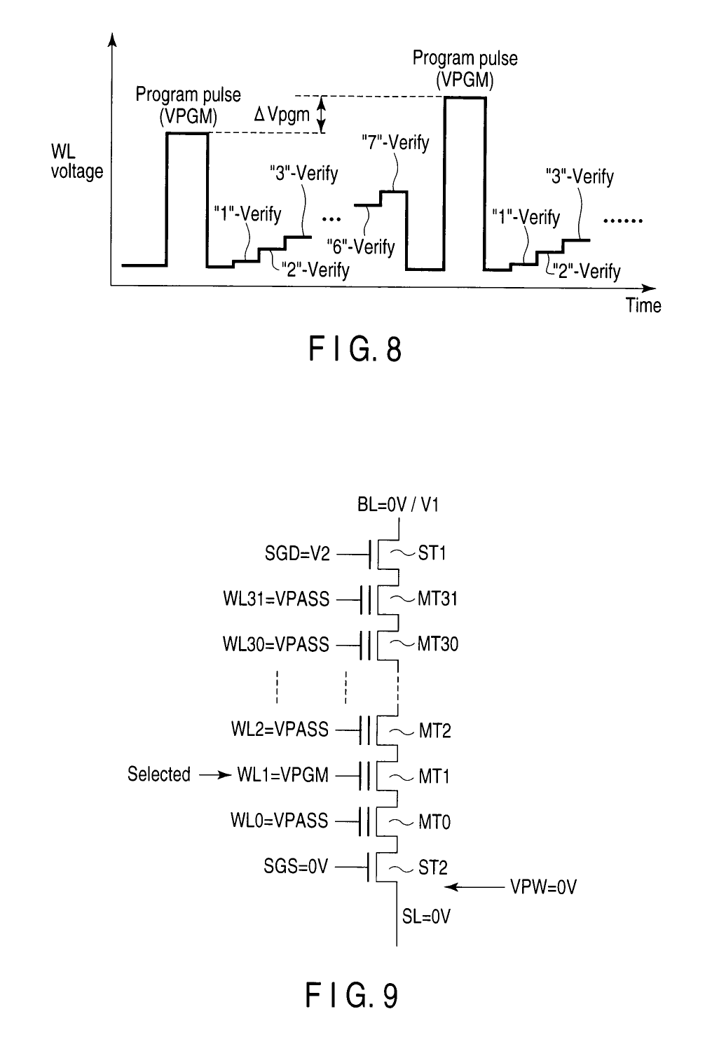

A write operation will be explained briefly with reference to FIG. 8. FIG. 8 is a graph showing a change in the voltage of the selected word line with respect to time in a write operation. As shown in FIG. 8, applying voltage VPGM to the word line causes a program operation to be performed, with the result that charges are injected into the charge accumulation layer 44. Thereafter, a verify operation is performed. That is, data is read, while the individual read levels (V01, V12, V23, . . . , V67) of FIG. 5 are being applied to the selected word line WL. By doing this, it is determined whether the memory cell transistor MT has reached a desired threshold value. If any one of the memory cell transistors MT has not reached the desired threshold value, voltage VPGM is stepped up and a program operation and a verify operation are performed again. Since the verify operation is the same as the read operation, explanation of it will be omitted. In the verify operation, the second voltage control circuit 22 may generate voltage Vsource with the temperature dependence as shown in FIG. 6 as in the read operation. Of course, Vsource may be caused to have temperature dependence in a read operation and be prevented from having temperature dependence in a verify operation.

FIG. 9 is a circuit diagram of a part of the NAND flash memory 10 in programming data. As in the read operation, a case where data is programmed on the memory cell transistor MT1 connected to word line WL1.

First, the sense amplifier 12 (not shown) transfers write data to a bit line BL. That is, if the threshold value of the memory cell transistor MT is raised by injecting charges into the charge accumulation layer 44, a write voltage (e.g., 0 V) is applied to the bit line BL. If no charge is injected, a write inhibit voltage (e.g., V1>0 V) is applied. The second voltage control circuit 22 and first voltage control circuit 18 apply 0 V to the source line SL and well region 42, respectively.

Then, the row decoder 15 selects word line WL1 and the word line driver 17 applies voltage VPGM to the selected word line WL1 and voltage VPASS to the unselected word lines WL0, WL2 to WL31. Voltage VPGM is a high voltage (e.g., about 20 V) for injecting charges into the charge accumulation layer 44. Voltage VPASS is a voltage that turns on a memory cell transistor MT, regardless of data the memory cell transistor MT holds.

The word line driver 17 applies voltage V2 and 0 V to the selection gate lines SGD, SGS, respectively. Voltage V2 is a voltage that turns on selection transistor ST1 when a write voltage (0 V) is applied to bit line BL and cuts off selection transistor ST1 when a write inhibit voltage (V1) is applied.

As a result, channels are formed in all the memory cell transistors MT0 to MT31 connected to word lines WL0 to WL31. If the write voltage (0 V) is applied to bit line BL, selection transistor ST1 goes on, causing the write voltage to be transferred to the channel of memory cell transistor MT1. As a result, a large potential difference develops between the control gate 46 and channel of memory cell transistor MT1, causing charges to be injected into the charge accumulation layer 44. If the write inhibit voltage V1 is applied to the bit line, selection transistor ST1 goes off, making the channel of memory cell transistor MT1 float. Then, the potential of memory cell transistor MT1 rises to almost VPGM by coupling with the control gate 46. As a result, the potential difference between the control gate 46 and channel decreases, suppressing the injection of charges into the charge accumulation layer 44.

<Effect>

As described above, with the semiconductor memory device of the first embodiment, the effect of a change in the threshold value due to temperature can be reduced. This effect will be explained in detail.

As described in the background, as the memory cell transistors MT are miniaturized further, variations in the threshold voltage of the memory cell transistors MT due to various factors become a problem. The aforementioned verify technique is known for reducing a variation in the threshold value. Use of the technique makes it possible to remedy memory cell transistors MT programmed insufficiently and perform control so as to decrease a variation in the threshold voltage sufficiently.

However, with the conventional verify technique, it was difficult to cope with a temperature crossing problem.

### 1. Temperature Crossing Problem

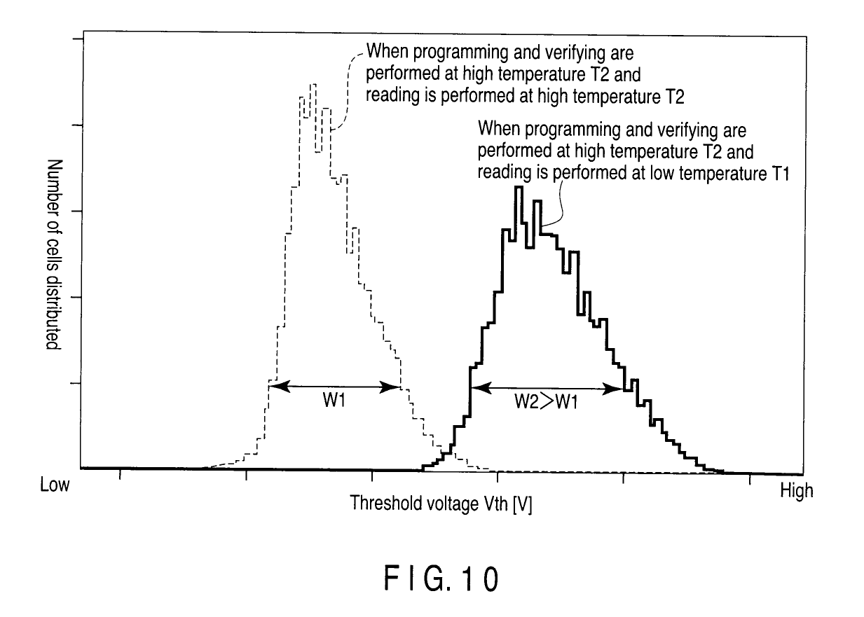

Temperature crossing will be explained briefly with reference to FIG. 10. FIG. 10 is a graph where the abscissa represents the threshold voltage and the ordinate represents the number of memory cell transistors MT. FIG. 10 shows the distribution of threshold voltages of memory cell transistors MT in the following two cases:

(1) The distribution of threshold voltages of memory cell transistors MT observed when writing (programming and verifying) is performed at high temperature T2 and then reading is performed at high temperature T2

(2) The distribution of threshold voltages of memory cell transistors MT observed when writing is performed at high temperature T2 and then reading is performed at low temperature T1 (<T2)

As shown in FIG. 10, width W2 of the threshold value distribution in case (2) where reading is performed at a temperature lower than in writing is greater than width W1 of the threshold value distribution in case (1) where reading is performed at the same temperature as in writing.

The same holds true for the reverse case. That is, although not shown in FIG. 10, the width of the threshold value distribution when reading is performed at a temperature higher than in writing is greater than width W1 of the threshold value distribution in case (1) where writing is performed at the same temperature as in the writing. That is, when reading is performed at a temperature different from that in writing, the threshold value distribution extends. This is a temperature crossing problem.

### 2. Cause of Temperature Crossing Problem

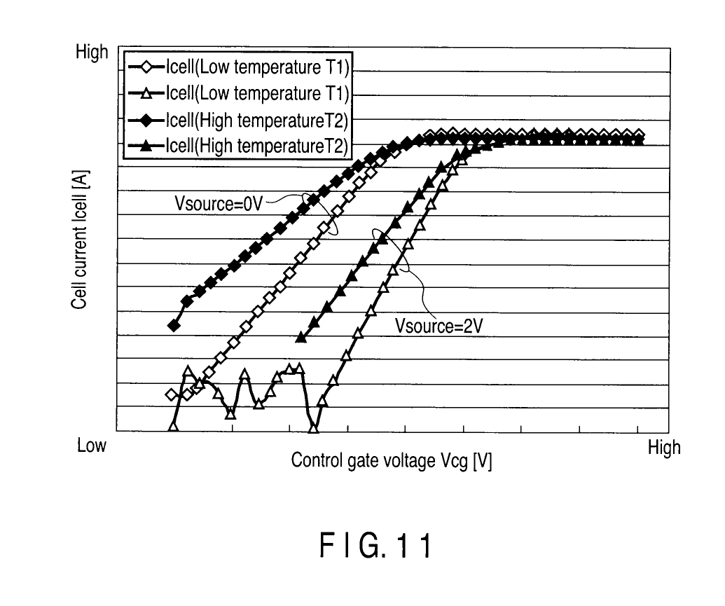

A temperature crossing problem is attributable to the change of the gradient of a cell current (drain current) characteristic with respect to the control gate voltage (hereinafter, simply referred to as a current-voltage characteristic) of memory cell transistor MT as the temperature changes. This will be explained with reference to FIG. 11. In FIG. 11, the abscissa represents control gate voltage Vcg and the ordinate represents cell current Icell. FIG. 11 shows a graph when Vsource (the potential difference between well region 42 and source line SL) is zero at each of low temperature T1 and high temperature T2 and a graph when Vsource is at 2 V at each of low temperature T1 and high temperature T2.

As shown in FIG. 11, in the current-voltage characteristic of memory cell transistor MT, the higher the temperature, the more easily cell current Icell flows in a region where cell current Icell varies with control gate voltage Vcg. On the other hand, the lower the temperature, the larger cell current Icell in a region where cell current Icell almost remains unchanged regardless of control gate voltage Vcg.

Furthermore, the lower the temperature, the greater the gradient (dI/dV) of cell current Icell in a region where cell current Icell varies with control gate voltage Vcg. That is, as the substrate temperature becomes lower, cell current Icell varies greatly with control gate voltage Vcg.

The temperature crossing problem results from the following: the gradient of the current-voltage characteristic becomes small as the temperature rises and the verify technique is for narrowing the distribution of threshold values by transforming the variation of the gradient into the distribution of charges stored in the charge accumulation layer.

That is, when writing (programming and verifying) is performed at low temperature and reading is performed at high temperature, the distribution width of charges in the charge accumulation layer is sufficiently narrow because the gradient of the current-voltage characteristic of memory cell transistor MT is large at low temperature. However, thereafter, when reading is performed at high temperature, the gradient of the current-voltage characteristic becomes small, making the distribution width of threshold voltages larger. That is, the threshold voltages are dispersed widely.

The same holds true in the reverse case. When writing (programming and verifying) is performed at high temperature and reading is performed at low temperature, the distribution width of charges in the charge accumulation layer becomes larger because the gradient of the current-voltage characteristic of memory cell transistor MT is small at high temperature. Accordingly, thereafter, even if the gradient becomes larger at low temperature, the distribution width of threshold voltages becomes larger because the large charge distribution width remains unchanged. That is, the threshold voltages are dispersed widely. The problem encountered particularly when writing is performed at high temperature and reading is performed at low temperature is not a well-known problem. Almost no measures have been taken to cope with such a problem.

As described above, when reading is performed at a temperature different from that in writing, the threshold voltages vary widely, which might decrease the reliability of the NAND flash memory. The wider variations in the threshold voltages might become a serious problem particularly in a multilevel NAND flash memory where the threshold distribution width of each level must be made narrower.

### 3. Possible Measures to Deal with Temperature Crossing

To solve the temperature crossing problem, it is necessary to decrease the difference between the gradient of the current-voltage characteristic at high temperature and that at low temperature. To achieve this, a method of applying a reverse bias between source line SL and well region 42 can be considered. In addition, to apply a reverse bias between source line SL and well region 42, a method of applying a negative bias to the well region 42 can be considered. However, with this method, it is necessary to charge a larger capacity than source line SL. Therefore, the following problems arise: the area used for the voltage generator circuit 19 becomes larger and a stable voltage cannot be supplied if the voltage generator circuit 19 is configured in a limited area.

### 4. First Embodiment

Accordingly, in the first embodiment, voltage Vsource is applied to source line SL to generate a potential difference between well region 42 and source line SL, thereby applying a reverse bias between source 47 and well region 42 of the NAND cell. By doing this, the difference between the gradient of the current-voltage characteristic at low temperature and that at high temperature is decreased.

In FIG. 11, as is clear from the comparison between black rhombic marks and black triangular marks and the comparison between outline rhombic marks and outline triangular marks that the gradient of the current-voltage characteristic of memory cell transistor MT can be made larger by applying Vsource. This results from the substrate bias effect.

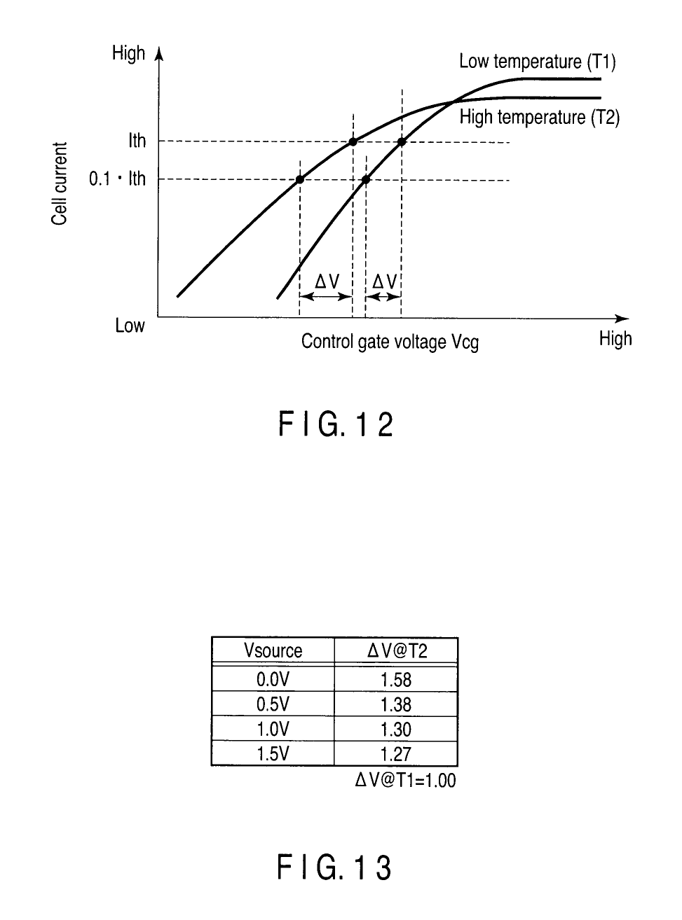

Control of the gradient by applying Vsource will be explained more specifically. Like FIG. 11, FIG. 12 shows the current-voltage characteristic of memory cell transistor MT at each of low temperature (T1) and high temperature (T2), with Vsource zero.

As shown in FIG. 12, let data determination threshold current in the sense amplifier 12 be called current Ith. Control gate voltage ΔV for changing (decreasing) the current by one digit from the current Ith is known as a swing (or S factor). Since the gradient is large as the temperature gets lower, the swing becomes smaller as the temperature gets lower if the other conditions are the same.

FIG. 13 is a table showing how ΔV at high temperature T2 changes with Vsource when ΔV at low temperature T1 is set at 1.00. As shown in FIG. 13, when Vsource is zero, the swing at high temperature T2 is 1.58 times that at low temperature T1. However, as Vsource is increased, the swing becomes smaller. When Vsource is 1.5 V, the swing at high temperature T2 is decreased to 1.27 times that at low temperature T1. That is, the difference between the current-voltage characteristic at low temperature and that at high temperature becomes smaller.

Then, the larger the temperature difference between the high temperature and low temperature, the larger a difference in the current-voltage characteristic (a difference in the swing). Accordingly, in the first embodiment, not only is a potential difference generated between well region 42 and source line SL, but also the potential difference is caused to have temperature dependence. More specifically, as the temperature becomes higher, the potential difference is made larger. That is, when the swing difference is small, voltage Vsource is made lower. When the swing difference is large, voltage Vsource is made higher. This reduces the difference between the current-voltage characteristic at low temperature and that at high temperature.

As a result, the temperature crossing problem of the expansion of the distribution of threshold voltages of the memory cell transistors MT due to the difference between the temperature in programming and that in reading is suppressed, which improves the reliability of the NAND flash memory.

Since only a necessary voltage is applied as voltage Vsource, the necessary potential difference between source line SL and well region 42 can be minimized as compared with a case where, for example, a constant voltage is applied to source line SL regardless of temperature. Accordingly, even if the p-n junction breakdown voltage between the well region 42 and impurity diffused layer 47 is low, the above effect is obtained.

### Second Embodiment

Next, a semiconductor memory device according to a second embodiment will be explained. The second embodiment relates to the second voltage control circuit 22 explained in the first embodiment. Hereinafter, only what differs from the first embodiment will be explained.

<Configuration of Second Voltage Control Circuit>

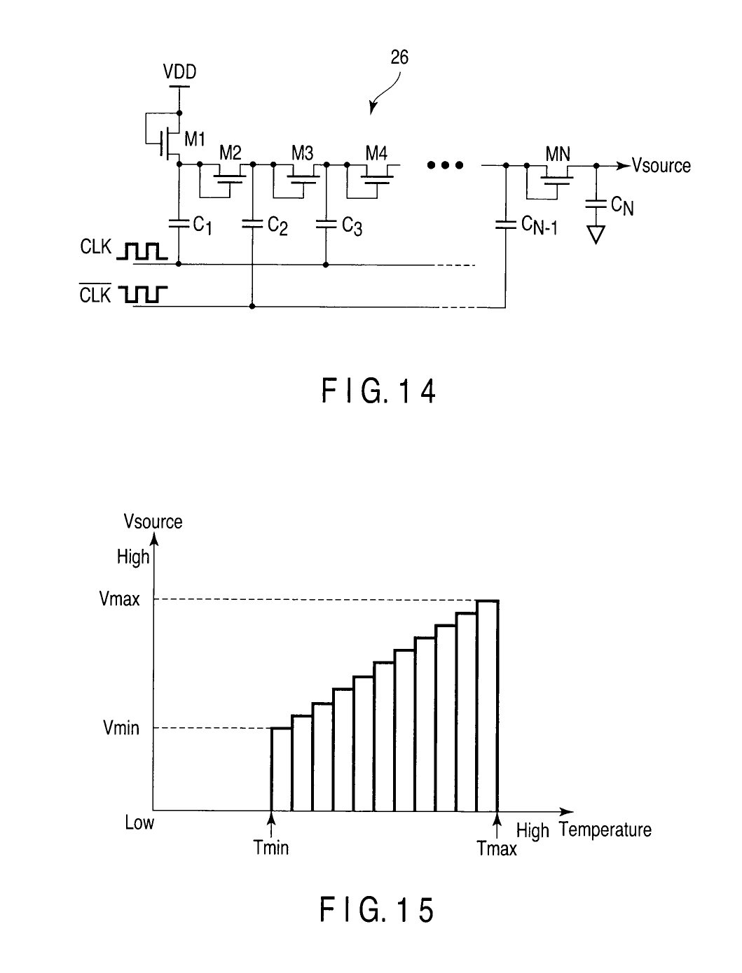

To generate voltage Vsource that rises with temperature, the second voltage control circuit 22 includes a positive charge pump circuit. FIG. 14 is a circuit diagram of a charge pump circuit included in the second voltage control circuit 22 of the second embodiment.

As shown in FIG. 14, the charge pump circuit 26 includes an N number (N is a natural number not less than 2) of n-channel MOS transistors M1 to MN and capacitor elements C1 to CN. Each of the MOS transistors M1 to MN has its gate connected to its drain and is equivalent to a diode. Drain of each of the MOS transistors M1 to MN functions as a cathode and source of that functions as an anode. MOS transistors M1 to MN have their current paths connected in series in such a manner that the preceding anode is connected to the following cathode. Voltage VDD is applied to the drain of MOS transistor M1 at the first stage.

Clock signal CLK is input via capacitor elements C1, C3, C5, . . . to the sources of MOS transistors M1, M3, M5, . . . at the odd-numbered stages, respectively. Inversion clock signal /CLK is input via capacitor elements C2, C4, C6, . . . to the sources of MOS transistors M2, M4, M6, . . . at the even-numbered stages, respectively. Capacitor element CN connected to the source of MOS transistor MN at the final stage is grounded.

With the above configuration, the voltages at both ends of each capacitor element Ci (i is a natural number in the range of 1 to (N−1)) are boosted alternately with clock signals CLK, /CLK, thereby outputting a positive voltage Vsource higher than external voltage VDD at the source of MOS transistor MN at the final stage.

Use of such a charge pump circuit 26 enables voltage Vsource shown in FIG. 15 to be obtained. FIG. 15 is a graph showing the change of voltage Vsource with temperature. As shown in FIG. 15, voltage Vsource is raised stepwise with temperature.

The charge pump circuit 26 is controlled on the basis of the monitoring result of the temperature monitor circuit 21. That is, if the temperature is low, the charge pump circuit 26 stops raising the voltage and, if the temperature is high, starts to raise the voltage. To perform such an operation, the second voltage control circuit 22 may include, for example, a comparator and a control unit in addition to the charge pump circuit 26. The control unit holds the relationship between temperature and voltage Vsource necessary for the temperature (e.g., a table corresponding to the graph of FIG. 15). Then, receiving the present temperature from the temperature monitor circuit 21, the control unit outputs a signal corresponding to the voltage necessary for the temperature. The comparator compares the signal with the output voltage of the charge pump circuit 26 to determine whether the output voltage has reached the necessary voltage, and outputs the result to the control unit. The output voltage compared at the comparator may be a voltage stepped down by, for example, resistive division. If the output voltage of the charge pump circuit 26 has reached the necessary voltage, the control unit stops clock signals CLK, /CLK. If not, the charge pump circuit 26 generates clock signals CLK, /CLK. Even with this configuration, the temperature characteristic of FIG. 15 is obtained.

Voltage Vsource may not be the output of the charge pump circuit 26. For example, the output of the charge pump circuit 26 may be regulated by a regulator circuit or the like to generate a desired voltage Vsource.

<Voltage Vsource>

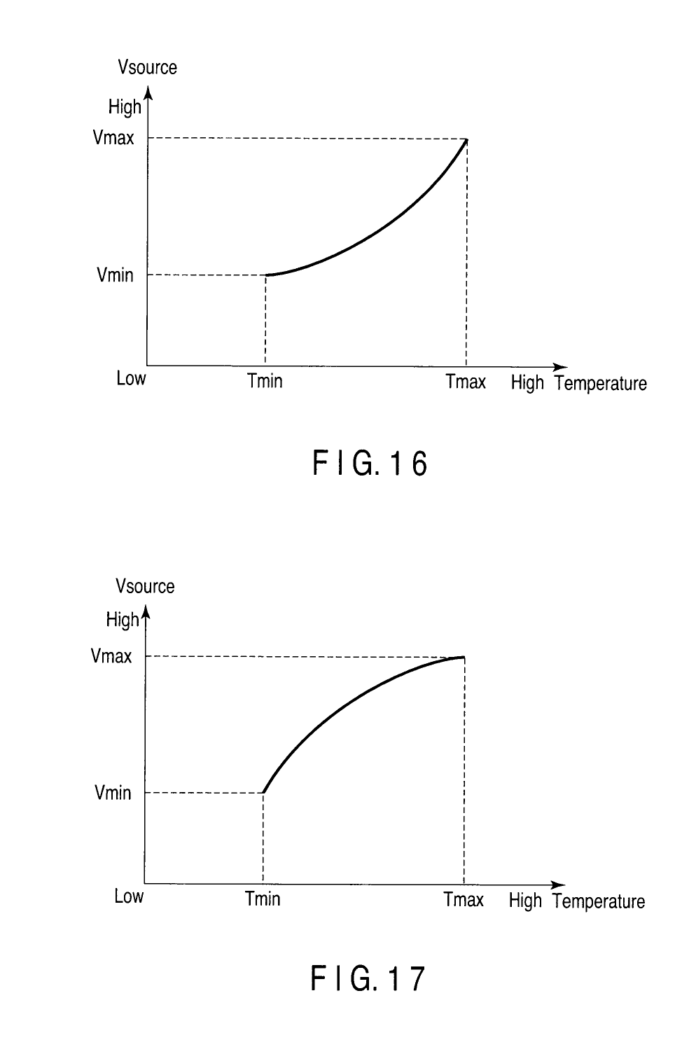

Next, another form of voltage Vsource will be explained. While in FIGS. 6 and 15, voltage Vsource has risen in proportion to a rise in the temperature, the embodiment is not limited to this. Other examples are shown in FIGS. 16 and 17. FIGS. 16 and 17 are graphs showing the dependence of voltage Vsource on temperature. As shown in FIGS. 16 and 17, there may be no proportional relation between voltage Vsource and temperature and voltage Vsource may change exponentially or logarithmically. Of course, the embodiment is not restricted to those examples. Voltage Vsource may change as shown in FIGS. 16 and 17 so as to increase stepwise. The way voltage Vsource changes is not restrictive, provided that voltage Vsource rises with temperature.

### Third Embodiment

Next, a semiconductor memory device according to a third embodiment will be explained. The third embodiment is such that the temperature monitor circuit 21 is used to control the sense level of the sense amplifier 12 in the first and second embodiments. Hereinafter, only what differs from the first and second embodiments will be explained.

<Configuration of NAND Flash Memory>

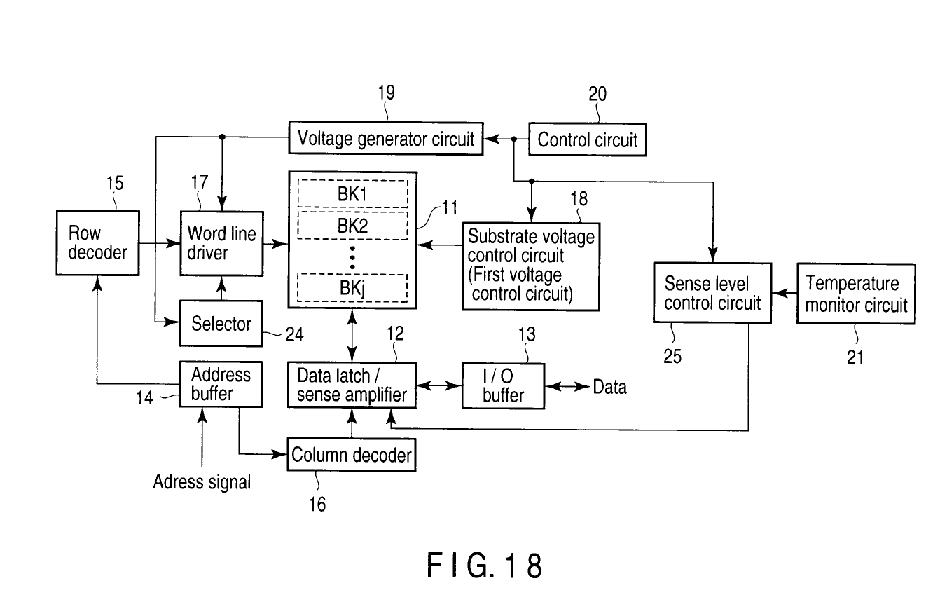

FIG. 18 is a block diagram of the NAND flash memory 10 according to the third embodiment. As shown in FIG. 18, the NAND flash memory 10 of the third embodiment is such that the second voltage control circuit 22 is eliminated and a sense level control circuit 25 is newly provided in the configuration of FIG. 1 explained in the first embodiment.

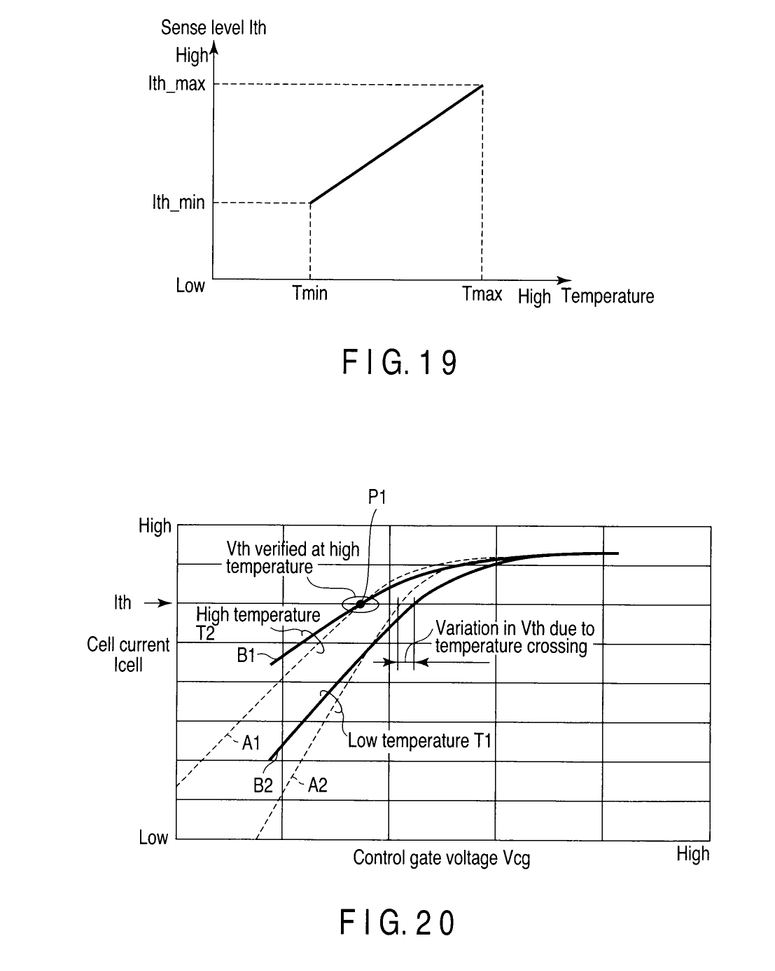

When data is read, the sense level control circuit 25 receives temperature information from the temperature monitor circuit 21. On the basis of the received temperature information, the sense level control circuit 25 controls the sense level of the sense amplifier 12. That is, the sense level control circuit 25 changes the level of determination as to whether memory cell transistor MT has been turned on or off, that is, the threshold value of determination of data, on the basis of temperature. FIG. 19 shows a change in the sense level of the sense amplifier 12 caused by the sense level control circuit 25. FIG. 19 is a graph showing the relationship between temperature and sense level Ith.

As shown in FIG. 19, the sense level control circuit 25 raises sense level Ith as temperature rises. That is, as temperature rises from Tmin to Tmax, Ith increases from its minimum Ith_min to its maximum Ith_max.

Sense level Ith may rise stepwise as shown in FIG. 15 as voltage Vsource explained in the first and second embodiments. Alternatively, sense level Ith may change exponentially or algorithmically as shown in FIGS. 16 and 17. That is, the way sense level Ith rises is not restrictive, provided that sense level Ith increases with temperature. The sense level control circuit 25 may perform similar control in not only a read operation but also a verify operation.

<Effect>

With the third embodiment, the adverse influence of a change in the threshold voltage due to temperature can be reduced as with the first embodiment. This effect will be explained in detail below.

As explained in the first embodiment, the threshold voltage of the memory cell transistors MT may vary because of temperature crossing, which may lead to erroneous reading. This will be explained with reference to FIG. 20. FIG. 20 shows the current-voltage characteristics at low temperature T1 and high temperature T2 of a memory cell transistor MT written into at high temperature T2. FIG. 20 shows two graphs for each of characteristics at T1 and T2; one with the best characteristic is shown on graphs A1, A2, and one with the worst characteristic is shown on graphs B1, B2. The better the characteristic, the steeper the gradient of the current-voltage characteristic.

As shown by graphs A1, B1 indicating a case at high temperature T2, writing is performed at high temperature T2 in such a manner that the current-voltage characteristics of a plurality of memory cell transistors MT to be written into cross each other at sense level Ith of the sense amplifier 12 (intersection P1). Accordingly, when data is read at high temperature T2, the threshold voltages hardly vary.

However, at low temperature T1, the current-voltage characteristics of the memory cell transistors MT change as shown by graphs A2, B2 and the intersection of graphs A2, B2 moves toward a smaller cell current Icell. Consequently, control gate voltages Vcg with which the memory cell transistors MT with the characteristics of graphs A2, B2 cause sense level Ith to flow differ from one another. That is, the threshold voltages vary. Accordingly, the following problem may arise: when a certain control gate voltage Vcg is applied, it is determined that a memory cell transistor MT with a good characteristic is on and a memory cell transistor MT with a poor characteristic is off, although they are both actually on.

With the configuration of the third embodiment, however, sense level Ith can be varied with temperature. More particularly, sense level Ith is raised as temperature rises. Accordingly, the above problem can be solved.

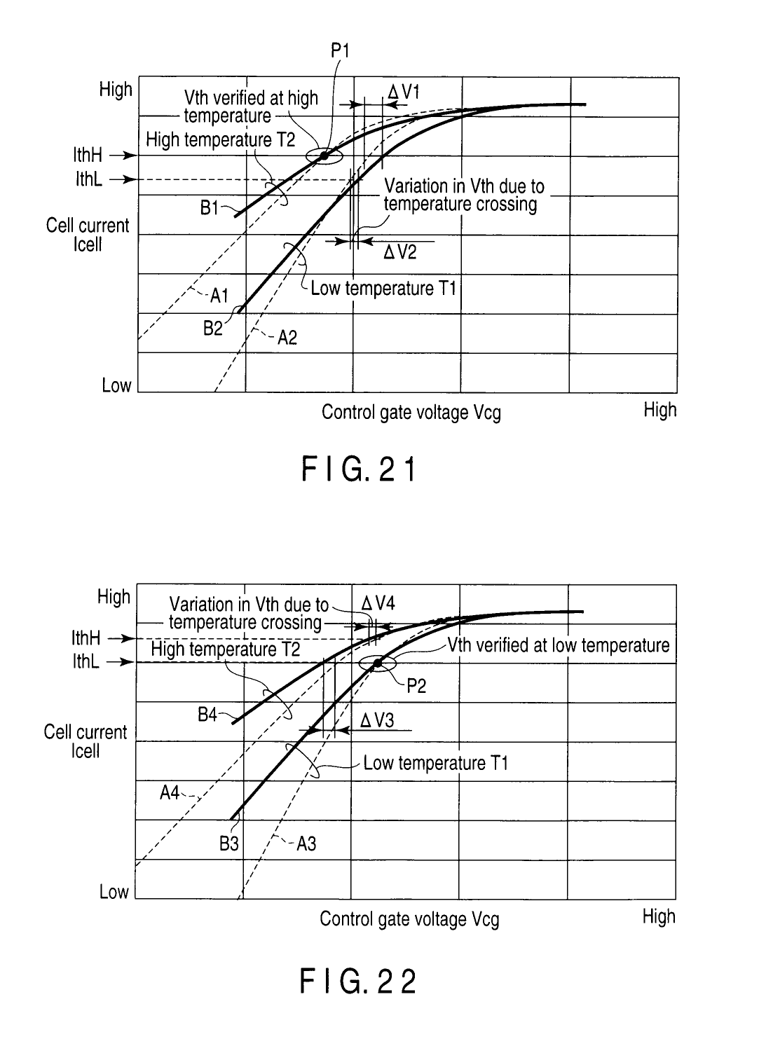

FIG. 21 shows the current-voltage characteristics at low temperature T1 and high temperature T2 of a memory cell transistor MT written into at high temperature T2. FIG. 21 shows two graphs for each of characteristics at T1 and T2; one with the best characteristic is shown on graph A1, A2, and one with the worst characteristic is shown on graphs B1, B2.

When writing is performed at high temperature T2, programming and verifying are performed in such a manner that graphs A1 and B1 cross each other at a certain sense level IthH (intersection P1). The characteristic of the memory cell transistor MT varies as shown by graphs A2 and B2 at low temperature. As temperature falls, the sense level control circuit 25 lowers the sense level of the sense amplifier 12 from IthH to IthL (<IthH). As a result, a variation in the threshold voltage decreases. That is, if the sense level is caused to remain unchanged at IthH regardless of temperature, a variation in the threshold voltage at low temperature is represented as ΔV1. By lowering the sense level to IthL, the variation can be reduced to ΔV2 (<ΔV1).

FIG. 22 shows the current-voltage characteristics at low temperature T1 and high temperature T2 of a memory cell transistor MT written into at low temperature T1. FIG. 22 shows two graphs for each of characteristics at T1 and T2; graphs A3 and A4 show the best characteristics and graphs B3 and B4 show the worst characteristics.

When writing is performed at low temperature T1, programming and verifying are performed in such a manner that graphs A3 and B3 cross each other at a certain sense level IthL (intersection P2). The characteristic of the memory cell transistor MT varies as shown by graphs A4 and B4 at high temperature T2. As temperature rises, the sense level control circuit 25 raises the sense level of the sense amplifier 12 from IthL to IthH (>IthL). As a result, a variation in the threshold voltage decreases. That is, when the sense level is caused to remain unchanged at IthL regardless of temperature, a variation in the threshold voltages at high temperature is represented as ΔV3. By raising the sense level to IthH, the variation can be reduced to ΔV4 (<ΔV3).

In FIGS. 21 and 22, it is desirable that the sense level may be changed so as to reduce variations (ΔV2, ΔV4) to zero. However, variations are not necessarily reduced to zero. By changing the sense level as shown in FIG. 19, a sufficient effect can be obtained.

### Fourth Embodiment

Next, a semiconductor memory device according to a fourth embodiment will be explained. The fourth embodiment relates to the configuration of the sense amplifier 12 of the third embodiment. Therefore, an explanation of the part excluding the sense amplifier will be omitted.

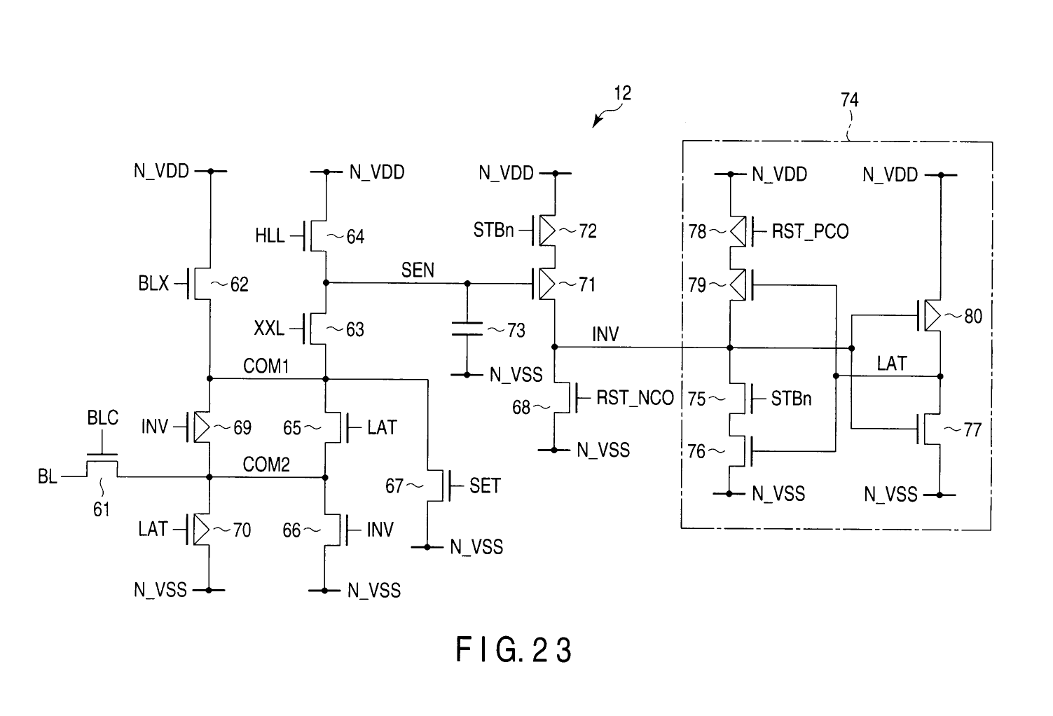

FIG. 23 is a circuit diagram of the sense amplifier 12. The configuration of FIG. 23 is provided for each of the bit lines BL. As shown in FIG. 23, the sense amplifier 12 includes n-channel MOS transistors 61 to 68, p-channel MOS transistors 69 to 72, a capacitor element 73, and a latch circuit 74.

One end of the current path of MOS transistor 61 is connected to a corresponding bit line BL and the other end is connected to node COM2 in the sense amplifier 12. Signal BLC is applied to the gate of MOS transistor 61.

One end of the current path of MOS transistor 70 is connected to node COM2 and the other end is connected to node N_VSS to which voltage VSS (e.g., 0 V) is applied. The gate of MOS transistor 70 is connected to node LAT. One end of the current path of MOS transistor 66 is connected to node COM2 and the other end is connected to node N_VSS. The gate of MOS transistor 66 is connected to node INV. One end of the current path of MOS transistor 69 is connected to node COM2 and the other end is connected to node COM1. The gate of MOS transistor 69 is connected to node INV. One end of the current path of MOS transistor 65 is connected to node COM2 and the other end is connected to node COM1. The gate of MOS transistor 65 is connected to node LAT. One end of the current path of MOS transistor 67 is connected to node COM1 and the other end is connected to node N_VSS. Signal SET is input to the gate of MOS transistor 67. One end of the current path of MOS transistor 62 is connected to node N_VDD and the other end is connected to node COM1. Signal BLX is input to the gate of MOS transistor 62. Power supply voltage VDD (positive voltage) is applied to node N_VDD. One end of the current path of MOS transistor 63 is connected to node SEN and the other end is connected to node COM1. Signal XXL is input to the gate of MOS transistor 63. One end of the current path of MOS transistor 64 is connected to node N_VDD and the other end is connected to node SEN. Signal HLL is input to the gate of MOS transistor 64. One electrode of capacitor element 73 is connected to node SEN and the other electrode is connected to node N_VSS. One end of the current path of MOS transistor 68 is connected to node INV and the other end is connected to node N_VSS. Signal RST_NCO is input to the gate of MOS transistor 68. One end of the current path of MOS transistor 71 is connected to node INV. The gate of MOS transistor 71 is connected to node SEN. One end of the current path of MOS transistor 72 is connected to node N_VDD and the other end is connected to the other end of the current path of MOS transistor 71. Signal STBn is input to the gate of MOS transistor 71.

Latch circuit 74 latches data at node INV, a connection node of MOS transistors 68 and 71. Latch circuit 74 includes n-channel MOS transistors 75 to 77 and p-channel MOS transistors 78 to 80.

One end of the current path of MOS transistor 75 is connected to node INV. Signal STBn is input to the gate of MOS transistor 75. One end of the current path of MOS transistor 76 is connected to node N_VSS and the other end is connected to the other end of the current path of MOS transistor 75. The gate of MOS transistor 76 is connected to node LAT. One end of the current path of MOS transistor 79 is connected to node INV. The gate of MOS transistor 79 is connected to node LAT. One end of the current path of MOS transistor 78 is connected to node N_VDD and the other end is connected to the other end of the current path of MOS transistor 79. Signal RST_PCO is input to the gate of MOS transistor 78. One end of the current path of MOS transistor 77 is connected to node N_VSS and the other end is connected to node LAT. The gate of MOS transistor 77 is connected to node INV. One end of the current path of MOS transistor 80 is connected to node N_VDD and the other end is connected to node LAT. The gate of MOS transistor 80 is connected to node INV.

The signals SET and RST_NCO are made high in a reset operation, which brings nodes COM1 and INV to the low level (0 V) and node LAT to the high level (VDD). In a normal operation, the signals SET and RST_NCO are made high, turning off MOS transistors 67 and 68. Signal RST_PCO is made high in a reset operation. In a normal operation, signal RST_PCO is made low.

Next, the operation of the sense amplifier in reading data will be explained.

(Case I)

First, Case I where a memory cell transistor MT goes on will be explained below.

First, a bit line BL is precharged. Suppose precharge level VPRE is at 0.7 V.

To perform precharging, MOS transistors 62 is turned on. Then, since the NAND cell is in the conducting state, current flows in bit line BL via the current paths of MOS transistors 62, 65, 69, 61 and nodes COM1, COM2. In the initial state, MOS transistors 66, 70 are off (INV=low or “L”, LAT=high or “H”). As a result, the potential of bit line BL is at about 0.7 V. That is, the potential of bit line BL is fixed to 0.7 V, while current is flowing from bit line BL to source line SL. MOS transistor 64 is turned on, charging capacitor element 73, which brings the potential at node SEN to about 2.5 V. MOS transistors 71, 72, 63 are off.

Next, node SEN is discharged. That is, MOS transistor 64 is turned off and MOS transistor 63 is turned on. Then, current flowing from node SEN to bit line BL causes node SEN to be discharged, which lowers the potential at node SEN to about 0.9 V.

Node SEN is further discharged. However, when the potential at node COM1 is about to drop below 0.9 V, MOS transistor 62 starts to supply current. As a result, the potential at node COM1 is kept at 0.9 V.

Next, data is sensed. That is, MOS transistor 72 is turned on. Since the potential at node SEN is at 0.9 V, MOS transistor 71 is on. Accordingly, the latch circuit 74 holds voltage VDD. That is, node INV is high (“H”) and node LAT is low (“L”). As a result, MOS transistors 66, 70 are on and MOS transistors 65, 69 are off. Therefore, current flows from bit line BL to node N_VSS, bringing the potential of bit line BL to zero.

(Case II)

Next, Case II where a memory cell transistor MT goes off will be explained below.

In this case, no current flows in bit line BL, keeping the voltage constantly at 0.7 V. Then, the potential at node SEN remains at about 2.5 V. Accordingly, MOS transistor 71 is off and the latch circuit 74 holds 0 V. That is, INV remains low (“L”) and LAT remains high (“H”).

In the sense amplifier 12 configured as described above, current sense level Ith can be changed by, for example, changing the threshold level of MOS transistor 71. To do this, for example, the back gate bias of the MOS transistor may be controlled. In this case, the back gate bias is increased as temperature rises, thereby increasing the threshold level of MOS transistor 71 (or making it difficult to turn on MOS transistor 71). This results in a rise in sense level Ith.

Alternatively, signal BLC may be controlled. That is, potential of the signal BLC may be decreased as temperature rises. The decreased signal BLC makes it difficult for current to flow in bit line BL (i.e., node SEN), resulting in a rise in sense level Ith.

In still another method, a resistance element may be provided in the sense amplifier 12 to use the change of current flowing in the resistance element with temperature.

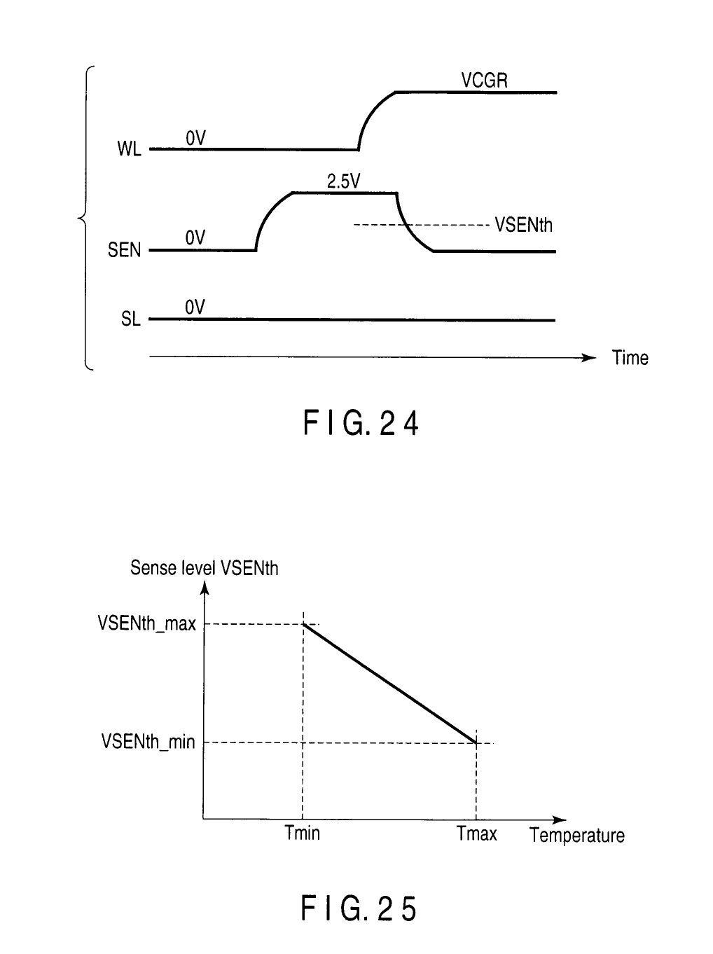

In the fourth embodiment, the sense level has been explained using current Ith. The sense level may be explained using a voltage. FIG. 24 is a timing chart to explain the potentials of the selected word line WL, node SEN, and source line SL in reading data.

As shown in FIG. 24, the potential at node SEN is set to 2.5 V and then MOS transistor 64 is turned off, which lowers the potential. At this time, voltage VSENth that determines how much the potential at node SEN has to drop to turn on MOS transistor 71 corresponds to the sense level of the sense amplifier 12. Accordingly, VSENth is caused to change with temperature. Before the potential at node SEN is set to 2.5 V, voltage VCGR may be applied to word line WL.

The characteristic of VSENth with respect to temperature is shown in FIG. 25. As shown in FIG. 25, as temperature rises from Tmin to Tmax, VSENth is lowered from its maximum SENth_max to its minimum VSENth_min. Controlling signal BLC and the back gate bias corresponds to changing VSENth as shown in FIG. 25.

### Fifth Embodiment

Next, a semiconductor memory device according to a fifth embodiment will be explained. The fifth embodiment is a combination of one of the first and second embodiments and one of the third and fourth embodiments.

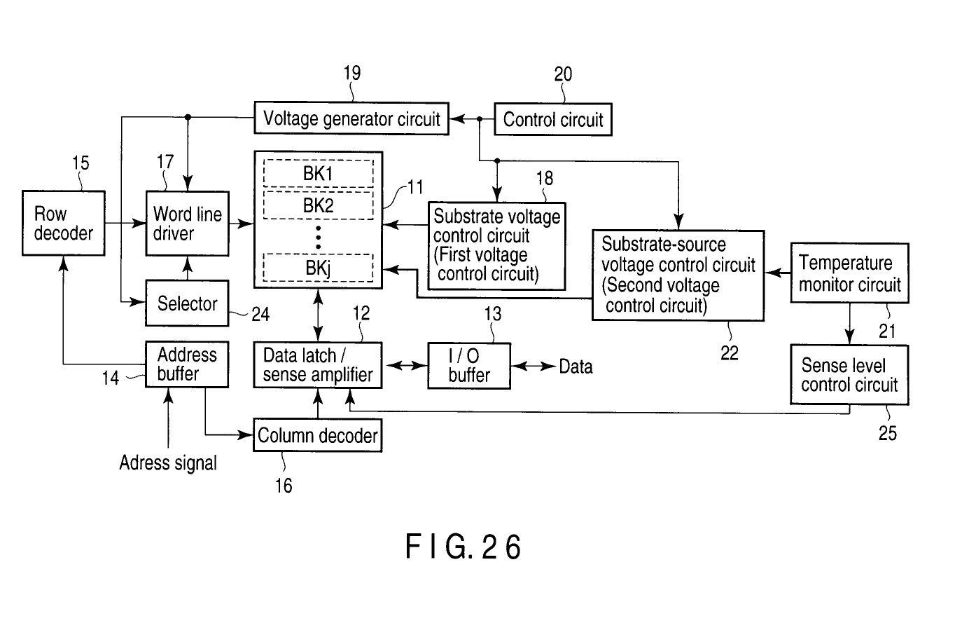

FIG. 26 is a block diagram of a NAND flash memory 10 according to the fifth embodiment. As shown in FIG. 26, the NAND flash memory 10 of the fifth embodiment is such that the sense level control circuit 25 explained with reference to FIG. 18 in the third embodiment is added to the configuration of FIG. 1 explained in the first embodiment. The operation of each of the circuit blocks is as explained in the first to fourth embodiments.

The configuration of the fifth embodiment produces the effects explained in the first and second embodiments and the effects explained in the third and fourth embodiments. That is, for example, even when a sufficient effect is not obtained by causing the potential of source line SL to have only temperature dependence, an adverse effect due to a variation in the threshold voltage is suppressed sufficiently by causing the sense level to have temperature dependence. The same holds true for the reverse case.

### Sixth Embodiment

Next, a semiconductor memory device according to a sixth embodiment will be explained. The sixth embodiment relates to a method of causing sense level Ith of the sense amplifier 12 to have temperature dependence which differs from the method described in the fourth embodiment. Hereinafter, only what differs from the third and fourth embodiment will be explained.

<Configuration of NAND Flash Memory>

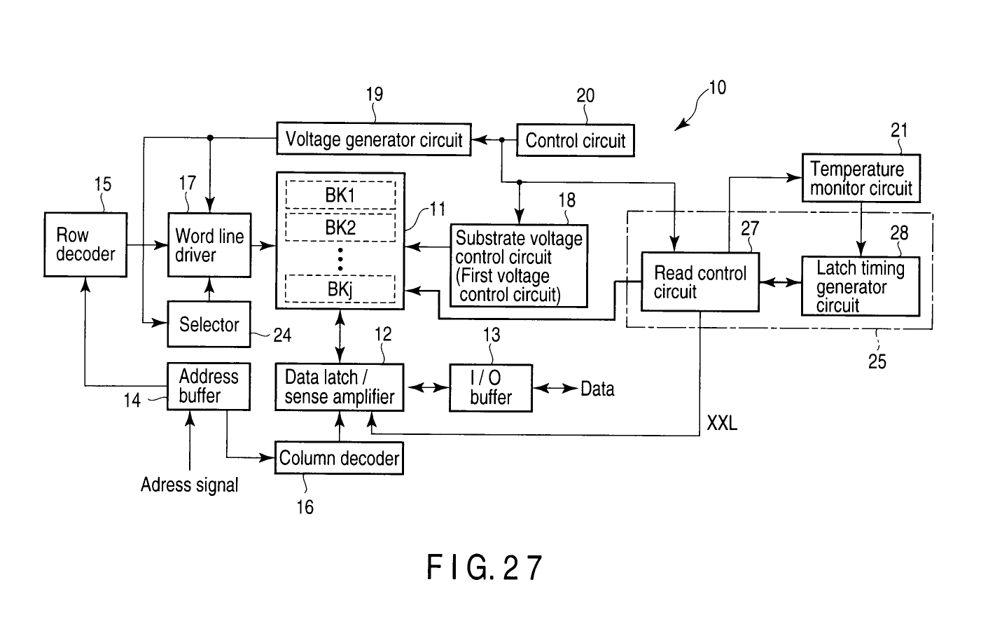

FIG. 27 is a block diagram of a NAND flash memory 10 according to the sixth embodiment. As shown in FIG. 27, the configuration of the sixth embodiment is such that the sense level control circuit 25 includes a read control circuit 27 and a latch timing generator circuit 28 in the configuration explained with reference to FIG. 18 in the third embodiment.

When data is read, the latch timing generator circuit 18 receives data latch start timing information from the read control circuit 27 and supplies data latch end timing information to the read control circuit 27. More specifically, the start timing information is information indicating the timing of making signal HLL low (“L”) (or negating signal HLL), that is, the discharge start timing of node SEN, in the configuration explained in FIG. 23. The end timing information is information indicating the timing of making signal XXL low (or negating signal XXL), that is, the discharge stop timing of node SEN.

When data is read, the read control circuit 27 instructs the sense amplifier 12 to terminate data latching, that is, terminate the discharging of node SEN on the basis of the end timing information received from the latch timing generator circuit 28. More specifically, the read control circuit 27 makes signal XXL low.

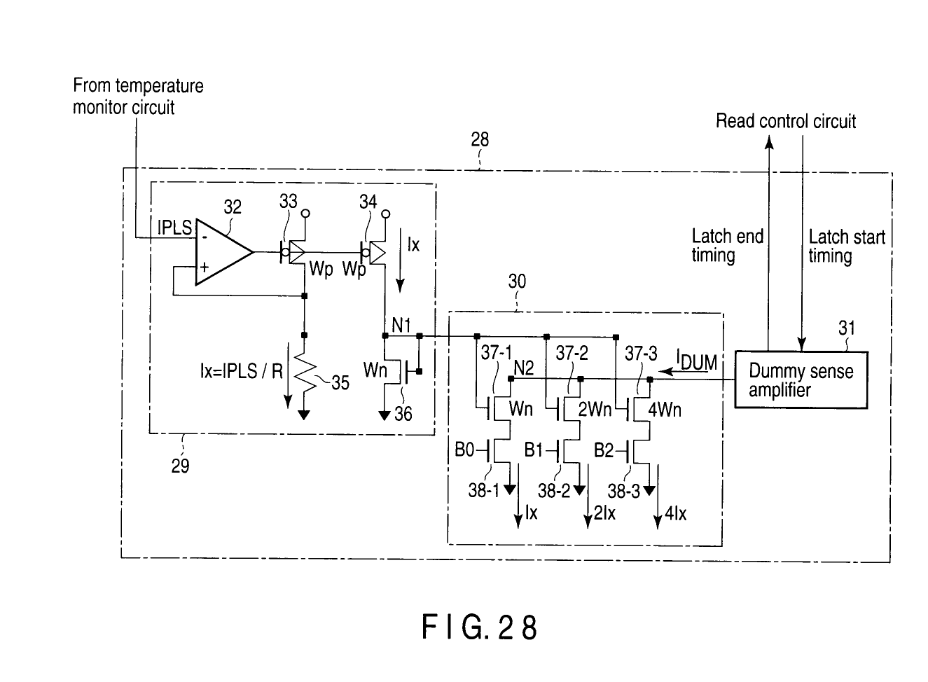

FIG. 28 is a circuit diagram of the latch timing generator circuit 28. As shown in FIG. 28, the latch timing generator circuit 28 roughly includes a temperature information control circuit 29, a dummy current generator circuit 30, and a dummy sense amplifier 31.

The temperature information control circuit 29 generates reference current Ix on the basis of temperature information supplied from the temperature monitor circuit 21 and supplies reference current Ix to the dummy current generator circuit 30. The temperature information control circuit 29 includes a comparator 32, p-channel transistors 33, 34, a resistance element 35, and an n-channel MOS transistor 36.

The comparator 32 compares current IPLS that is supplied from the temperature monitor circuit 21 and has a current corresponding to temperature with reference current Ix. If current IPLS is larger than reference current Ix, the comparator 32 outputs a low (“L”) level and, if not, outputs a high (“H”) level. That is, current IPLS is input to the inverting input terminal (−) of the comparator 32 and current Ix is input to the noninverting input terminal (+).

A power supply voltage (e.g., VDD) is applied to the source of MOS transistor 33. The output signal of the comparator 32 is input to the gate of MOS transistor 33. The drain of MOS transistor 33 is connected to the noninverting input terminal of the comparator 32 and one end of the resistance element 35. The gate width of MOS transistor 33 is Wp. The other end of the resistance element 35 is grounded. Current (IPLS/R) flowing in the resistance element 35 is used as reference current Ix, where R is the resistance of the resistance element 35.

A power supply voltage (e.g., VDD) is applied to the source of MOS transistor 34. The output signal of the comparator 32 is input to the gate of MOS transistor 34. The drain of MOS transistor 34 is connected to the drain and gate of MOS transistor 36. The gate width of MOS transistor 34 is Wp equal to the gate width of the MOS transistor 33. That is, MOS transistor 34 and MOS transistor 33 form a current mirror circuit. Therefore, the drain current of MOS transistor 34 is equal to reference current Ix. The gate width of MOS transistor 34 may differ from that of MOS transistor 33. MOS transistor 36 has a gate width of Wn. The source of MOS transistor 36 is grounded.

With this configuration, the gate potential of MOS transistor 33 is controlled so that reference current Ix may be equal to current IPLS. That is, reference current Ix based on the resistance R of the resistance element 35 is controlled suitably according to temperature. Then, according to the voltage supplied from the comparator 32, MOS transistor 34 controls the voltage at connection node N1 with MOS transistor 36 suitably according to temperature.

Next, the dummy current generator circuit 30 will be explained. The dummy current generator circuit 30 includes three groups, each including two MOS transistors 37, 38 connected in series. That is, the dummy current generator circuit 30 includes n-channel MOS transistors 37-1 to 37-3, 38-1 to 38-3. MOS transistors 37-1 to 37-3 have gate widths Wn, 2Wn, 4Wn, respectively. Their drains are connected in common to node N2. Their gates are connected to node N1. That is, a voltage corresponding to reference current Ix is input to the gates.

Signals B0 to B2 are input to the gates of MOS transistors 38-1 to 38-3, respectively. The drains of MOS transistors 38-1 to 38-3 are connected to the sources of MOS transistors 37-1 to 37-3, respectively. The sources are grounded. Signals B0 to B2 are supplied from, for example, the control circuit 20. The gate widths of MOS transistors 38-1 to 38-3 may be Wn, 2Wn, 4Wn, respectively, or the same value larger than 4Wn. MOS transistors 38-1 to 38-3 have only to function sufficiently as switches.

With the above configuration, dummy current I_{DUM} flowing in node N2 is represented by the following equation (1):

I_{DUM}=B0×Ix+B1×2Ix+B2×4Ix (1)

Here, B0 to B2 correspond to signals B0 to B2. Accordingly, if B0=“1” and B1=B2=“0,” MOS transistor 38-1 goes on and MOS transistors 38-2, 38-3 go off, giving dummy current I_{DUM}=Ix. In addition, if B0=B1=B2=“1,” MOS transistors 38-1 to 38-3 all go on, giving dummy current I_{DUM}=7Ix. That is, signals B0 to B2 determine the upper limit of the generated dummy current I_{DUM}. They also determine sense level Ith of the sense amplifier 12 as described later.

The number of groups of MOS transistors 37, 38 is not limited to 3 and may be 2 or not less than 4. For example, if the gate width of an i-th MOS transistor 37-i is Wi and signal Bi is input to an i-th MOS transistor 38-i, dummy current I_{DUM} is represented by the following equation (2):

I_{DUM}=ΣBi×(Wi/Wn)·Ix (2)

where i=0 to N (N is a natural number not less than 2).

The control circuit 20 controls signals B0 to B2 in such a manner that, for example, dummy current I_{DUM} increases as temperature rises. As an example, at lower than temperature T1, signals B0 to B2 are controlled so as to give B0=“1” and B1=B2=“0.”Furthermore, in a temperature range of T2≦T<T3, signals B0 to B2 are controlled so as to give B0=B1=“1” and B2=“0.” The control unit 20 may include such a table in advance.

Next, the configuration of the dummy sense amplifier 31 will be explained. Like the sense amplifier 12, the dummy sense amplifier 31 has the configuration of FIG. 23. The operation of the dummy sense amplifier 31 is as explained in the fourth embodiment. That is, the dummy sense amplifier 31 senses dummy current I_{DUM} flowing in node N2. At that time, the dummy sense amplifier 31 makes signal HLL low (“L”) (or negates signal HLL) according to start timing information supplied from the read control circuit 27. Then, the dummy sense amplifier 31 determines data using a certain threshold value VSENth. In the dummy sense amplifier 31, the threshold value VSENth is a fixed value. Then, the dummy sense amplifier 31 outputs the timing of node SEN reaching VSENth as end timing information to the read control circuit 27.

The sense amplifier 31 may be formed of only the latch circuit 74 of FIG. 23 so as to cause dummy current I_{DUM} to correspond to current flowing in MOS transistor 71 of FIG. 23.

<Method of Changing Sense Level Ith>

Next, a method of changing sense level Ith of the sense amplifier 12 according to temperature will be explained.

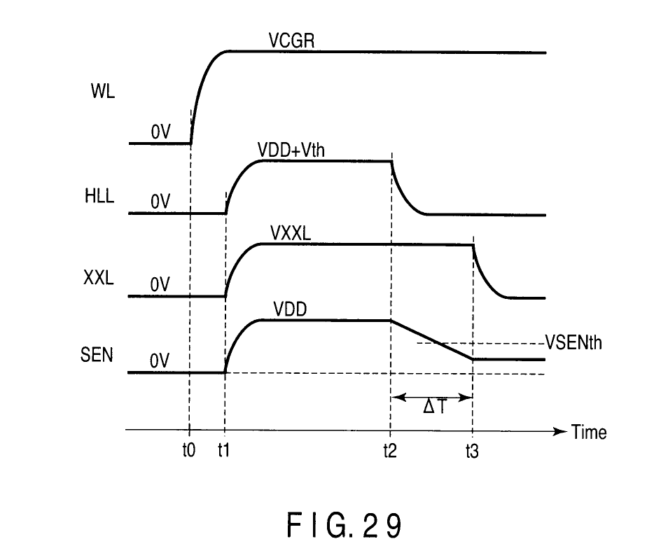

FIG. 29 is a timing chart showing changes in the voltages of word line WL, signals HLL, XXL, and node SEN when data is read, particularly when the selected memory cell is turned on. A variation in each of the signals is almost as shown in FIG. 24 explained in the fourth embodiment.

As shown in FIG. 29, at time t2, the control circuit 20 makes signal HLL low (“L”) to discharge node SEN. This corresponds to the data latch start timing. At this time, signal XXL remains high (“H”) (at potential VXXL). The potential at node SEN falls at a certain rate. Thereafter, at time t3, the control circuit 20 makes signal XXL low (“L”). This corresponds to the data latch end timing. As a result, MOS transistor 63 goes off, causing node SEN to go to a constant potential. Then, MOS transistor 72 is turned on, making the potentials at node INV and LAT high (“H”) and low (“L”), respectively.

Here, sense level Ith is represented by the following equation (3):

Ith=C(SEN)×ΔV/ΔT (3)

where C(SEN) is the capacity of capacitor element 73 of FIG. 23, Vthp is the threshold voltage of MOS transistor 71, and ΔV=|Vthp|.

Since capacity C (SEN) is normally a parasitic capacity of an interconnection, it is a factor automatically determined by the interconnection pattern. It is sometimes difficult to change threshold voltage Vthp. Accordingly, in the sixth embodiment, time ΔT is changed. Time ΔT corresponds to the period from time t2 to time t3 in FIG. 29.

Therefore, in the sixth embodiment, at the same time that the discharging of bit line BL is started (or the sensing of data is started) in the memory cell array 11, the operation of the dummy sense amplifier 31 is started in the latch timing generator circuit 28. Dummy current I_{DUM} sensed by the dummy sense amplifier 31 is current dependent on a change in the temperature sensed by the temperature monitor circuit 21. Thereafter, when the dummy sense amplifier 31 has sensed that the potential has reached sense level VSENth as a result of discharging, the sense amplifier 12 terminates the discharging of bit line BL (or terminates the sensing of data).

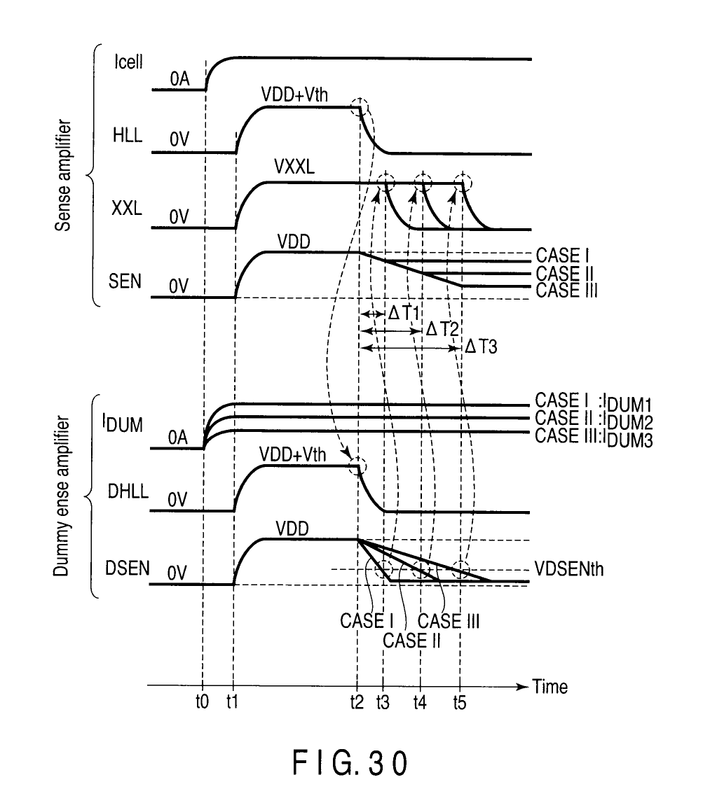

A concrete example of the above operations will be explained with reference to FIG. 30. FIG. 30 is a timing chart showing temporal changes in cell current Icell, signals HLL, XXL, and the potential at node SEN in the sense amplifier 12, and dummy current I_{DUM}, signal HLL, and the potential at node SEN in the dummy sense amplifier 31, when data is read. Hereinafter, to simplify explanation, signal HLL is referred to as signal DHLL and node SEN as node DSEN in the dummy sense amplifier 31. In addition, sense level VSENth is referred to as VDSENth in the dummy sense amplifier 31.

As shown in FIG. 30, suppose Icell and I_{DUM} start to flow at, for example, t0. Both may or may not start to flow at the same time. As described above, the magnitude of I_{DUM} can be varied according to temperature and signals B0 to B2. Hereinafter, cases where I_{DUM} is I_{DUM}1, I_{DUM}2, and I_{DUM}3 will be explained as Cases I, II, and III, respectively. Case I is a case where temperature is the highest, Case II is a case where temperature is the next highest, and Case III is a case where temperature is the lowest, satisfying the expression I_{DUM}1>I_{DUM}2>I_{DUM}3.

Thereafter, at time t2, signal HLL in the sense amplifier 12 is made low. At the same time, signal DHLL in the dummy sense amplifier 31 is also made low. Information on the timing is supplied from the read control circuit 27 to the dummy sense amplifier 28. As a result, the potentials at nodes SEN, DSEN fall at a certain rate. At this time, the rate at which the potential at node DSEN drops depends on the magnitude of current I_{DUM}. More specifically, the larger current I_{DUM}, the potential falls faster. Accordingly, in Case I, the potential at node DSEN reaches VDSENth at time t3. In Case II, the potential at node DSEN reaches VDSENth at time t4 later than in Case I. In Case III, the potential at node DSEN reaches VDSENth at time t5 later than in Case II.

Then, when the potential at node DSEN has arrived at VDSENth, the dummy sense amplifier 31 informs the read control circuit 27 of the arrival time as the end timing. As a result, the read control circuit 27 makes signal XXL low at time t3 in Case I, signal XXL low at time t4 in Case II, and signal XXL low at time t5 in Case III. That is, as shown in FIG. 30, ΔT explained in equation (3) is made ΔT1 in Case I, ΔT2 in Case II, and ΔT3 in Case III, satisfying the expression ΔT1<ΔT2<ΔT3.

As described above, the larger dummy current I_{DUM}, the shorter ΔT is made. The shorter ΔT is, the higher the potential at node SEN becomes. That is, with a higher potential as a reference, a comparison is made with sense level VSENth. This is synonymous with a rise in sense level Ith and a fall in VSENth as shown in FIG. 25.

<Effect>

As described above, with the configuration of the sixth embodiment, data can be sensed using the optimum sense level Ith differing with temperature. Therefore, the expansion of the threshold value distribution due to temperature crossing can be suppressed.

With the sixth embodiment, there is no need to form a new element in the limited region of the sense amplifier 12. It is also unnecessary to form a new well region in the sense amplifier 12. At least one element must be formed in the semiconductor chip to form the latch timing generator circuit 28 and need not be provided for each sense amplifier 12. Accordingly, an increase in the chip area can be minimized. Moreover, there is no need to generate a voltage that changes nonlinearly according to a change in temperature. In these respects, it may be said that the configuration of the sixth embodiment is preferable to the method explained in the fourth embodiment.

With the sixth embodiment, a characteristic superior to several propositions described in the background can be obtained. For example, in the method disclosed in, for example, Jpn. Pat. Appln. KOKAI Publication No. 2001-357687, dummy cells different from actual cells and a dummy sense amplifier are used. With the configuration disclosed in Jpn. Pat. Appln. KOKAI Publication No. 2001-357687, the effect of processing variations cannot be suppressed sufficiently in an ultrafine NAND flash memory of the order of gigabytes. Therefore, if temperature has changed, its effect on the memory cells is not identical with that on the dummy cells. In addition, its effect on adjacent cells cannot be taken into consideration. Moreover, the timing of sensing is determined in the middle of manufacturing, the timing is not necessarily suitable for a reference.

In the method disclosed in Jpn. Pat. Appln. KOKAI Publication No. 2002-025285, the sense amplifier compares current generated by the reference current generator circuit with cell current. With this configuration, however, it is necessary to take into account the temperature characteristics of the memory cells, reference current generator, and sense amplifier and therefore suitable control is almost impossible.

In the method disclosed in Jpn. Pat. Appln. KOKAI Publication No. 2009-522705, a change in the temperature characteristic of a MOS transistor used in an STB signal generator which is input to the sense amplifier is used without using a reference current generator circuit. With this configuration, however, a temperature crossing problem cannot be solved.

In contrast, with the configuration of the sixth embodiment, the above problems can be solved. That is, since no dummy cell is used, the influences of processing variations and influences from adjacent memory cells are eliminated. In addition, signals B0 to B2 are programmable. Therefore, even after the manufacture, the sense timing can be adjusted optimally. Since only the temperature characteristic of the memory cells has to be taken into consideration, a temperature crossing problem can be solved simply with high accuracy.

The sixth embodiment can, of course, be applied to the fifth embodiment. While a data read operation has been explained, the sixth embodiment may be applied to a verify-read operation carried out in a write operation. Moreover, the configuration of the sense amplifier 12 and dummy sense amplifier 31 is not limited to the configuration of FIG. 23. For instance, they may be configured to sense a voltage. Sense amplifiers of various configurations may be used.

In the method of sensing times t3, t4, t5 in FIG. 30, various techniques may be used. For instance, in the dummy sense amplifier 31, signal DHLL may be kept high until after time t5 and signal STBn be made low at time t2. In this case, since the potential at node INV changes from low to high when the potential at node DSEN has dropped below VDSENth, the change may be sensed. That is, ΔT may be the period from when signal HLL is made low until the potentials at nodes INV and LAT in the dummy sense amplifier 31 are changed from low and high to high and low, respectively. At this time, signal DHLL is made low (or negated) later than signal HLL and signal STBn in the dummy sense amplifier 31 is made high (or asserted) earlier than signal STBn in the sense amplifier 12. While in FIG. 30, signal XXL has been made low at the same time the potential at node DSEN has reached VDSENth, the former may not be necessarily made low at the same time the latter reaches VDSENth. There may be a time difference between the time that the potential at node DSEN reaches VDSENth and the time that signal XXL is made low. That is, the dummy sense amplifier 31 may be configured to make signal XXL low later as temperature becomes higher.

As described above, in a semiconductor memory device according to each of the first to sixth embodiments, a NAND flash memory 10 include a temperature monitor 21 and a source line voltage controller 22 and/or sense level controller 25. The temperature monitor 21 monitors a temperature of the semiconductor chip (substrate 40) in which the NAND flash memory 10 has been integrated. The source line voltage controller 22 applies voltage Vsource to the source line SL in a read operation, thereby generating a potential difference between the source line SL and semiconductor substrate (well region 42). At this time, the source line voltage controller 22 increases the potential difference according to a rise in the temperature monitored by the temperature monitor 21 and induces a reverse bias between the source of the second selection transistor ST 2 and the semiconductor substrate (well region 42). The sense level controller 25 controls a sense level Ith in a sense amplifier 12 according to a change in the temperature monitored by the temperature monitor 21 in the read operation.

While in the embodiments, voltage Vsource has been positive, it is not necessarily positive. For instance, Vsource may be zero or negative, depending on the potential VPW of the well region 42. That is, a potential difference corresponding to the temperature has only to develop between the source line SL and well region 42. In this case, as shown in FIG. 6, the potential of source line SL is set to be higher than the potential of the well region 42 (reverse bias is applied between the source 47 of selection transistor ST2 and the well region 42). To achieve this, the second voltage control circuit 22 may control the voltage Vsource on the basis of information on the potential applied to the well region 42 by the first voltage control circuit 18.

While in the above embodiments, the sense amplifier 12 has sensed current, it may sense a voltage. That is, when data is read, the sense amplifier 12 may make bit line BL float with precharge voltage VPRE and sense a change in the potential of bit line BL when voltage VCGR is applied to the selected word line WL. In this case, a change in bit line BL corresponds to that at node SEN of FIG. 24. The sense amplifier 12 may control determination threshold VBLth of bit line BL. Even when the sense amplifier 12 controls VBLth, the control method is the same as in FIG. 25.

In FIGS. 6, 16, 17, 19, and 25, voltage Vsource and the sense level have been changed in the overall guaranteed operating range (Tmin to Tmax) of a NAND flash memory. However, they may not be changed in the overall range. For instance, voltage Vsource and the sense level may be kept constant in a low temperature range and, in a range higher than a certain temperature, they may be changed. In contrast, voltage Vsource and the sense level may be kept constant in a high temperature range and, in a range lower than a certain temperature, they may be changed.

Furthermore, in the embodiments, a NAND flash memory has been used. The embodiments may be applied to not only a NAND flash memory but also other EEPROMs, including a NOR flash memory, and semiconductor memories in general where a variation in the threshold value due to temperature becomes a problem.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory cells which are formed on a semiconductor substrate and include a stacked gate including a charge accumulation layer;
a first selection transistor and a second selection transistor which are formed on the semiconductor substrate, the memory cells are connected in series between a source of the first selection transistor and a drain of the second selection transistor;
a source line which is connected to a source of the second selection transistor;
a temperature monitor which monitors a temperature of the semiconductor substrate; and
a source line voltage controller which applies a voltage to the source line, in a read operation, in such a manner that a potential difference between the source line and the semiconductor substrate increases according to a rise in the temperature monitored by the temperature monitor and that a reverse bias is applied between the source of the second selection transistor and the semiconductor substrate.

2. The device according to claim 1, wherein the source line voltage controller applies the voltage increasing with the temperature to the source line in a temperature range where the temperature exceeds a specific voltage.

3. The device according to claim 1, wherein the voltage increases stepwise as the temperature rises.

4. The device according to claim 1, further comprising:
a bit line which is connected to a drain of the first selection transistor;
a sense amplifier which senses data read from one of the memory cells onto the bit line in the read operation; and
a sense level controller which controls a sense level in the sense amplifier according to a change in the temperature monitored by the temperature monitor in the read operation.

5. The device according to claim 4, wherein the sense amplifier senses a current flowing in the bit line, and
the sense level controller controls the sense level for the current in the sense amplifier.

6. The device according to claim 5, wherein the sense level controller raises the sense level for the current as the temperature rises.

7. The device according to claim 4, wherein the sense level controller includes a dummy current generator which generates a dummy current corresponding to the temperature monitored by the temperature monitor, and
a dummy sense amplifier which senses the dummy current generated by the dummy current generator, and
sense end timing of the sense amplifier is determined by sense end timing of the dummy sense amplifier.

8. The device according to claim 7, wherein the dummy current generator increases the dummy current as temperature rises.

9. The device according to claim 7, wherein the sense amplifier determines data on the basis of a potential at a first node discharged according to the current flowing in the bit line,
the dummy sense amplifier determines data on the basis of a potential at a second node discharged according to the dummy current, and
the sense end timing of the sense amplifier and the dummy sense amplifier is the timing of stopping discharge at the first node and the second node, respectively.

10. The device according to claim 9, wherein a time length between a start and an end of the discharge of the first node is made shorter as the temperature rises.

11. The device according to claim 7, wherein the sense level controller further includes a reference current generator which generates a reference current according to the temperature monitored by the temperature monitor, and
the dummy current generator generates the dummy current configurable on the basis of the reference current.

12. A semiconductor memory device comprising:
a plurality of memory cells which are formed on a semiconductor substrate and include a stacked gate including a charge accumulation layer;
a first selection transistor and a second selection transistor which are formed on the semiconductor substrate, the memory cells are connected in series between a source of the first selection transistor and a drain of the second selection transistor;
a bit line which is connected to a drain of the first selection transistor;
a source line which is connected to a source of the second selection transistor;
a temperature monitor which monitors a temperature of the semiconductor substrate;
a sense amplifier which senses data read from one of the memory cells onto the bit line in a read operation; and
a sense level controller which controls a sense level in the sense amplifier according to a change in the temperature monitored by the temperature monitor in the read operation.

13. The device according to claim 12, wherein the sense amplifier senses a current flowing in the bit line, and
the sense level controller controls the sense level for the current in the sense amplifier.

14. The device according to claim 13, wherein the sense level controller raises the sense level for the current as the temperature rises.

15. The device according to claim 12, wherein the sense level controller includes a dummy current generator which generates a dummy current corresponding to the temperature monitored by the temperature monitor, and
a dummy sense amplifier which senses the dummy current generated by the dummy current generator, and
sense end timing of the sense amplifier is determined by sense end timing of the dummy sense amplifier.

16. The device according to claim 15, wherein the dummy current generator increases the dummy current as temperature rises.

17. The device according to claim 15, wherein the sense amplifier determines data on the basis of a potential at a first node discharged according to the current flowing in the bit line,
the dummy sense amplifier determines data on the basis of a potential at a second node discharged according to the dummy current, and
the sense end timing of the sense amplifier and the dummy sense amplifier is the timing of stopping discharge at the first node and second node, respectively.

18. The device according to claim 17, wherein time length between a start and an end of the discharge of the first node is made shorter as the temperature rises.

19. The device according to claim 15, wherein the sense level controller further includes a reference current generator which generates a reference current according to the temperature monitored by the temperature monitor, and
the dummy current generator generates the dummy current configurable on the basis of the reference current.
